(19) United States
(12) Patent Application Publication
(10) Pub. No.: US 2026/0362682 A1
(43) Pub. Date: Nov. 12, 2026

(54) 3D DYNAMIC RANDOM ACCESS MEMORY (DRAM) AND METHODS FOR FABRICATING 3D-DRAM

(71) Applicant: LAM RESEARCH CORPORATION, Fremont, CA (US)

(72) Inventors: Benjamin VINCENT, Meudon (FR); Joseph ERVIN, San Jose, CA (US)

(21) Appl. No.: 19/123,957

(22) PCT Filed: Oct. 19, 2023
(86) PCT No.: PCT/US2023/035485

§ 371 Date: Apr. 24, 2025

Related U.S. Application Data
(60) Provisional application No. 63/420,179, filed on Oct. 28, 2022.
(60) Provisional application No. 63/438,083, filed on Jan. 10, 2023.

(51) Int. Cl. H10B 12/00

(52) U.S. Cl. CPC H10B 12/488; H10B 12/02

(57) ABSTRACT

A three-dimensional (3D) dynamic random-access memory (DRAM) includes a substrate and a plurality of nanosheet transistors stacked vertically on a surface of the substrate. Each of the nanosheet transistors comprises a gate, a source, and a drain. A plurality of bitlines is connected to corresponding ones of the drains of the nanosheet transistors on one side of the plurality of nanosheet transistors. A plurality of capacitors is stacked vertically on the substrate, extend parallel to a surface of the substrate, and are connected to corresponding ones of the sources on an opposite side of the plurality of nanosheet transistors.

### CROSS-REFERENCE TO RELATED APPLICATIONS

This application claims the benefit of U.S. Provisional Application No. 63/420,179, filed on Oct. 28, 2022, and U.S. Provisional Application No. 63/438,083, filed on Jan. 10, 2023. The entire disclosures of the applications referenced above are incorporated herein by reference.

### FIELD

The present disclosure relates to memory, and more particularly to 3D dynamic random-access memory (3D-DRAM) and methods for fabricating 3D-DRAM.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Dynamic random-access memory (DRAM) stores each bit of data in a memory cell. Each memory cell includes a capacitor and one or more transistors. The memory is typically based on metal-oxide-semiconductor (MOS) technology. Advanced DRAM is typically processed with two transistors per active area (e.g., FinFET based). The transistor gates are connected to (or contacted to) wordlines. Drains are contacted to bitlines. Storage node contacts connect sources of the transistors to vertical metal capacitors of the memory cell. Current 3D DRAM architectures have encountered scaling saturation due to a high aspect ratio required for contact and capacitor processing.

### SUMMARY

A three-dimensional (3D) dynamic random-access memory (DRAM) includes a substrate and a plurality of nanosheet transistors stacked vertically on a surface of the substrate, wherein each of the nanosheet transistors comprises a gate, a source, and a drain. The 3D DRAM includes a first staircase, a plurality of bitline contacts, a plurality of bitlines connected by the plurality of bitline contacts to corresponding ones of the drains of the nanosheet transistors at the first staircase, a plurality of second staircases, a plurality of third staircases, a plurality of capacitor contacts, and a plurality of storage node contacts including first ends connected to corresponding ones of the sources of the plurality of nanosheet transistors. A plurality of capacitors stacked vertically on the substrate and extending parallel to a surface of the substrate. First ends of the plurality of capacitors located adjacent to the plurality of nanosheet transistors are connected to first ends of corresponding ones the plurality of capacitor contacts at corresponding ones of the plurality of second staircases. Second ends of the plurality of capacitor contacts are connected to second ends of corresponding ones of the plurality of storage node contacts at corresponding ones of the plurality of third staircases.

In other features, the first staircase comprises a two-dimensional (2D) staircase. The first staircase descends in first and second orthogonal directions relative to the surface of the substrate. At least a portion of the first staircase extends below the surface of the substrate. The first staircase and the plurality of bitlines are arranged on one side of the plurality of nanosheet transistors. The plurality of second staircases, the plurality of third staircases, and the capacitors are arranged on an opposite side of the plurality of nanosheet transistors.

In other features, the capacitor contacts are J-shaped and have a plurality of vertical lengths in a direction transverse to the surface of the substrate. The plurality of second staircases is interleaved between the plurality of third staircases. The plurality of second staircases descends in a direction towards the plurality of nanosheet transistors. The plurality of third staircases ascends in a direction towards the plurality of nanosheet transistors. The gates of the plurality of nanosheet transistors comprise forksheet gates corresponding to word lines.

A three-dimensional (3D) dynamic random-access memory (DRAM) includes a substrate and a plurality of nanosheet transistors stacked vertically on a surface of the substrate. Each of the nanosheet transistors comprises a gate, a source, and a drain. A plurality of bitlines is connected to corresponding ones of the drains of the nanosheet transistors on one side of the plurality of nanosheet transistors. A plurality of capacitors is stacked vertically on the substrate, extend parallel to a surface of the substrate, and are connected to corresponding ones of the sources on an opposite side of the plurality of nanosheet transistors.

In other features, the plurality of bitlines is connected by ae plurality of bitline contacts to corresponding ones of the drains of the nanosheet transistors at the first staircase.

In other features, the 3D DRAM includes a plurality of second staircases, a plurality of third staircases, a plurality of capacitor contacts, and a plurality of storage node contacts including first ends connected to corresponding ones of the sources of the plurality of nanosheet transistors. First ends of the plurality of capacitors located adjacent to the plurality of nanosheet transistors are connected to first ends of corresponding ones the plurality of capacitor contacts at corresponding ones of the plurality of second staircases. Second ends of the plurality of capacitor contacts are connected to second ends of corresponding ones of the plurality of storage node contacts at corresponding ones of the plurality of third staircases.

In other features, the first staircase comprises a two-dimensional (2D) staircase. The first staircase descends in first and second orthogonal directions relative to the surface of the substrate. At least a portion of the first staircase extends below the surface of the substrate. The capacitor contacts are J-shaped and have a plurality of vertical lengths in a direction transverse to the surface of the substrate. The plurality of second staircases is interleaved between the plurality of third staircases.

In other features, the plurality of second staircases descends in a direction towards the plurality of nanosheet transistors and the plurality of third staircases ascends in a direction towards the plurality of nanosheet transistors. The gates of the plurality of nanosheet transistors comprise forksheet gates corresponding to word lines.

A method for fabricating a three-dimensional (3D) dynamic random-access memory (DRAM) includes depositing alternating first and second layers on a surface of a substrate; patterning active areas of a plurality of nanosheet transistors in the alternating first and second layers; patterning forksheet gates of the plurality of nanosheet transistors; selectively doping portions of the plurality of nanosheet transistors; and forming a first staircase to provide a plurality of connection locations to a plurality of bitline contacts on one side of the plurality of nanosheet transistors and a plurality of second staircases providing a plurality of connection locations to a plurality of storage node contacts on an opposite side of the plurality of nanosheet transistors.

In other features, the first staircase descends in first and second orthogonal directions relative to the surface of the substrate. The method includes forming a plurality of capacitors on an opposite side of the plurality of nanosheet transistors. The plurality of capacitors is stacked vertically on the substrate and extend parallel to the surface of the substrate.

In other features, the method includes forming a plurality of third staircases between the plurality of second staircases to provide connection locations for first ends of the plurality of capacitors. The plurality of second staircases ascends in a direction towards the plurality of nanosheet transistors and the plurality of third staircases descend in a direction towards the plurality of nanosheet transistors. The method includes patterning a plurality of capacitor contacts connecting the first ends of the plurality of capacitors to the plurality of storage node contacts. The plurality of capacitor contacts is J-shaped and have a plurality of vertical lengths in a direction transverse to the surface of the substrate.

In other features, the method includes patterning and depositing a plurality of bitlines connected to corresponding ones of the plurality of bitline contacts. At least a portion of the first staircase extends below the surface of the substrate.

A three-dimensional (3D) dynamic random-access memory (DRAM) includes a substrate and a first array of nanosheet transistors arranged in a first vertical stack on the substrate. The first array comprises N levels of rows each including M nanosheet transistors. A second array of nanosheet transistors is arranged in a second vertical stack on the substrate, wherein the second array comprises N levels of rows each including M nanosheet transistors, wherein M and N are integers greater than one. N bitline layers stacked and vertically aligned with the N levels of the first and second arrays of nanosheet transistors. First sides of channels of the M nanosheet transistors in each of the N levels of the first array of nanosheet transistors are connected to first sides of corresponding ones of the N bitline layers and first sides of channels of the M nanosheet transistors in each of the N levels of the second array of nanosheet transistors are connected to second sides of corresponding ones of the N bitline layers such that each of the N bitline layers is connected to 2*M nanosheet transistors.

In other features, a first one of N vertical bitlines is connected to a first one of the N bitline layers. Others of the N vertical bitlines are connected to one of the N bitline layers and extend though and are isolated from one or more of the N bitline layers. 2M vertical wordlines are connected to gates of the first array of nanosheet transistors and the second array of nanosheet transistors.

In other features, M of the 2M vertical wordlines are connected to gates of vertically aligned ones of the first array of nanosheet transistors, respectively. M of the 2M vertical wordlines are connected to gates of vertically aligned ones of the second array of nanosheet transistors, respectively.

In other features, the 2M vertical wordlines surround the gates of corresponding ones of the first array of nanosheet transistors and the second array of nanosheet transistors. A first array of bridges connects the first sides of the channels of the N bitline layers to the first array of nanosheet transistors. The first array of bridges includes N levels of rows each including M bridges. A second array of bridges connecting the second sides of the channels of the N bitline layers to the second array of nanosheet transistors, wherein the second array of bridges includes N levels of rows each including M bridges.

In other features, a first array of capacitors is connected to second sides of the channels of the first array of nanosheet transistors, wherein the first array of capacitors includes N levels of rows each including M capacitors; and

In other features, a second array of capacitors connected to a second side of the channels of the second array of nanosheet transistors, wherein the second array of capacitors includes N levels of rows each including M capacitors. A first array of bridges connects the first array of capacitors to the second sides of the channels of the first array of nanosheet transistors. The first array of bridges includes N levels of rows each including M bridges; and
a second array of bridges connecting the second array of capacitors to the second sides of the channels of the second array of nanosheet transistors, wherein the second array of bridges includes N levels of rows each including M bridges.

In other features, the first array of capacitors comprises metal-isolator-metal capacitors. The first array of capacitors comprises inner metal layers connected to the second sides of the channels of the first array of nanosheet transistors, isolator layers surrounding the inner metal layers, and outer layers surrounding the inner metal layers.

A method for fabricating a three-dimensional (3D) dynamic random-access memory (DRAM) includes arranging a first array of nanosheet transistors in a first vertical stack on the substrate, wherein the first array comprises N levels of rows each including M nanosheet transistors; arranging a second array of nanosheet transistors in a second vertical stack on the substrate, wherein the second array comprises N levels of rows each including M nanosheet transistors, wherein M and N are integers greater than one; stacking and vertically aligning N bitline layers with the N levels of the first and second arrays of nanosheet transistors; and connecting first sides of channels of the M nanosheet transistors in each of the N levels of the first array of nanosheet transistors to first sides of the N bitline layers and connecting first sides of channels of the M nanosheet transistors in each of the N levels of the second array of nanosheet transistors to second sides of the N bitline layers such that each of the N bitline layers is connected to 2*M nanosheet transistors.

In other features, the method includes connecting a first one of the N vertical bitlines to one of the N bitline layers; and connecting others of the N vertical bitlines to one of the N bitline layers and extending though and are isolated from one or more of the N bitline layers.

In other features, the method includes connecting 2M vertical wordlines to gates of the first array of nanosheet transistors and the second array of nanosheet transistors. In other features, the method includes connecting M of the 2M vertical wordlines to gates of vertically aligned ones of the first array of nanosheet transistors, respectively. In other features, the method includes connecting M of the 2M vertical wordlines to gates of vertically aligned ones of the second array of nanosheet transistors, respectively. The 2M vertical wordlines surround the gates of corresponding ones of the first array of nanosheet transistors and the second array of nanosheet transistors.

In other features, the method includes connecting the first sides of the channels of the N bitline layers to the first array of nanosheet transistors using a first array of bridges, wherein the first array of bridges includes N levels of rows each including M bridges. The method includes connecting the second sides of the channels of the N bitline layers to the second array of nanosheet transistors using a second array of bridges, wherein the second array of bridges includes N levels of rows each including M bridges.

In other features, the method includes connecting a first array of capacitors to second sides of the channels of the first array of nanosheet transistors, wherein the first array of capacitors includes N levels of rows each including M capacitors. The method includes connecting a second array of capacitors to second sides of the channels of the second array of nanosheet transistors, wherein the second array of capacitors includes N levels of rows each including M capacitors.

In other features, the method includes connecting the first array of capacitors to the second sides of the channels of the first array of nanosheet transistors using a first array of bridges, wherein the first array of bridges includes N levels of rows each including M bridges. In other features, the method includes connecting the second array of capacitors to the second sides of the channels of the second array of nanosheet transistors using a second array of bridges, wherein the second array of bridges includes N levels of rows each including M bridges.

In other features, the first array of capacitors comprises metal-isolator-metal capacitors. The first array of capacitors comprises inner metal layers connected to the second sides of the channels of the first array of nanosheet transistors, isolator layers surrounding the inner metal layers, and outer layers surrounding the inner metal layers.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A is a cross sectional view of an example of a 2D DRAM cell;

FIG. 1B is a cross sectional view of an example of the 2D DRAM cell of FIG. 1A rotated in a first plane;

FIG. 1C is a cross sectional view of an example of the 2D DRAM cell of FIG. 1B rotated in a second plane;

FIGS. 2A to 2C are perspective views of an example of a 3D DRAM integrated circuit according to the present disclosure;

FIGS. 3A to 3C are perspective views of an example of a 2D staircase, alternating up and down staircases, and capacitor contacts in a 3D DRAM according to the present disclosure;

FIG. 4 is a flowchart of an example of a method for fabricating the 3D DRAM according to the present disclosure;

FIGS. 5A to 5C are perspective views illustrating an example of active area patterning and cladding according to the present disclosure;

FIGS. 6A to 6D are perspective views illustrating an example of wordline or forksheet gate patterning according to the present disclosure;

FIGS. 7A to 7C are perspective views illustrating an example of sacrificial SiGe replacement by a dielectric material according to the present disclosure;

FIGS. 8A to 8H are perspective views illustrating an example of further formation of the first staircase (in a first direction) and a plurality of second staircases according to the present disclosure;

FIGS. 9A to 9H are perspective views illustrating an example of further formation of the first staircase in a second direction according to the present disclosure;

FIGS. 10A to 10I are perspective views illustrating an example of horizontal capacitor formation according to the present disclosure;

FIGS. 11A to 12I are perspective views illustrating an example of formation of a plurality of third staircases between the plurality of second staircases according to the present disclosure;

FIGS. 13A to 13F are perspective views illustrating an example of bridge (capacitor contacts) and bitlines according to the present disclosure;

FIGS. 14A and 14B are plan views illustrating examples of bitlines shared by multiple write lines, transistors, and capacitors according to the present disclosure;

FIGS. 15A to 15C are perspective views illustrating an example of a 3D DRAM with a stack of transistors, bitlines connected to the transistors according to the present disclosure;

FIG. 15D is a perspective view illustrating examples of multi-bridge connections between bitlines and transistors and capacitors and transistors according to the present disclosure;

FIG. 15E is a perspective view illustrating examples of capacitors according to the present disclosure;

FIG. 16 is a perspective view of examples of the multi-bridges of the 3D DRAM according to the present disclosure;

FIGS. 17 and 18A to 18E are perspective views of examples of sacrificial silicon layers perforated by vertical vias landing at different elevations according to the present disclosure;

FIG. 19 is a perspective view of examples of multi-bridges during processing according to the present disclosure;

FIG. 20 is a flowchart of an example of a method for fabricating a 3D DRAM according to the present disclosure;

FIGS. 21A and 21B are perspective views illustrating an example of active area patterning according to the present disclosure;

FIGS. 22A and 22B are perspective views illustrating an example of gate patterning according to the present disclosure;

FIGS. 23A to 23D are perspective views illustrating an example of nanosheet isolation according to the present disclosure;

FIGS. 24A to 24H are perspective views illustrating an example of multi-bridge formation according to the present disclosure;

FIGS. 25A to 25D are perspective views illustrating another example of multi-bridge formation according to the present disclosure;

FIGS. 26A to 26F are perspective views illustrating an example of bitline patterning according to the present disclosure;

FIGS. 27A to 27H are perspective views illustrating an example of capacitor processing according to the present disclosure;

FIG. 28 is a perspective view illustrating an example of gate isolation according to the present disclosure;

FIGS. 29A to 29E are perspective views illustrating an example of formation of top contacts to bitlines according to the present disclosure;

FIGS. 30A to 30B are perspective views illustrating an example of formation of wordlines and capacitor formation according to the present disclosure; and

FIGS. 31A to 31C illustrate the 3D DRAM with some outer layers omitted for illustration according to the present disclosure.

In the drawings, reference numbers may be reused to identify similar and/or identical elements.

### DETAILED DESCRIPTION

A 3D-DRAM architecture according to the present disclosure rotates 2D DRAM cells in two planes (and then stacks the 2D DRAM cells) in order to overcome patterning challenges of current designs. The 3D-RAM architecture includes horizontal nanosheet transistors (e.g., two transistors per bit). The 3D-RAM architecture arranges storage node contacts and drain contacts on opposite sides of the nanosheet transistors. The 3D-RAM architecture includes a 2-D staircase allowing connection of bitlines to corresponding drains of the nanosheet transistors. The 3D-RAM architecture also includes interleaved (or alternating) up and down staircases to connect horizontal stacked capacitors to horizontal storage node contacts.

These features allow the 3D-RAM architecture to be implemented using horizontal nanosheet transistors. The 3D-RAM architecture described herein can be processed using existing materials and processes that have already been developed for advanced logic/memory (as compared to other FinFET-based transistor 3D-NAND designs that are not fully developed).

As can be appreciated, the following description is illustrated using specific materials and integration steps to provide further understanding of the 3D DRAM architecture according to the present disclosure. However, the 3D DRAM architecture according to the present disclosure is not limited to these examples and other materials and/or other integration steps can be used without departing from the scope of the present disclosure.

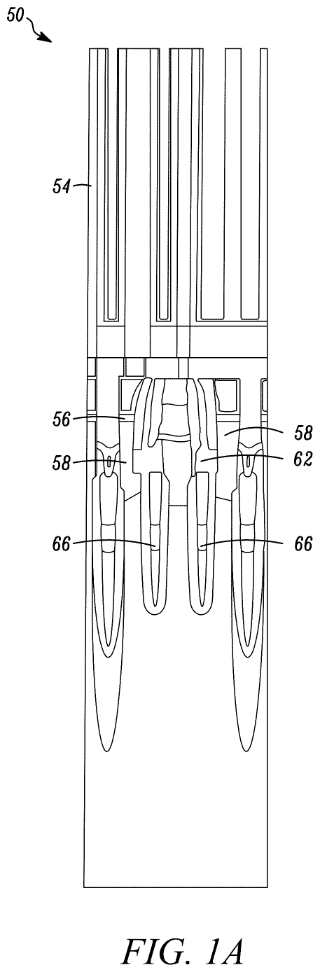

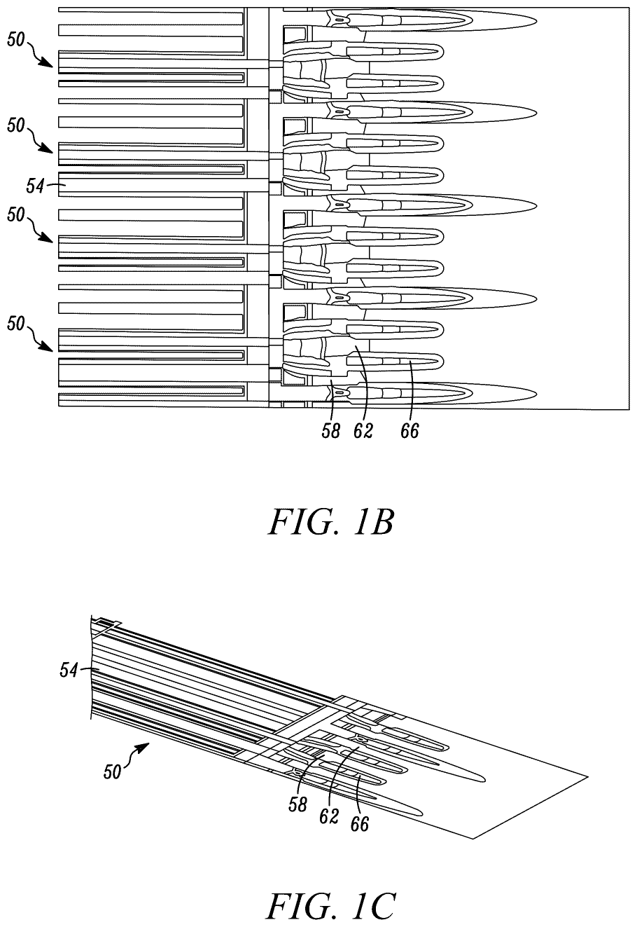

Referring now to FIG. 1A, a memory cell 50 for 2D DRAM is shown. The memory cell 50 includes capacitors 54 extending vertically, sources 56, storage node contacts 58, drains 62, and gates 66. The memory cell 50 is arranged with the capacitors 54 extending upwardly from the memory cell 50. Further improvements can be achieved by transitioning from 2D DRAM to 3D DRAM. However, implementing 3D DRAM has been difficult to achieve.

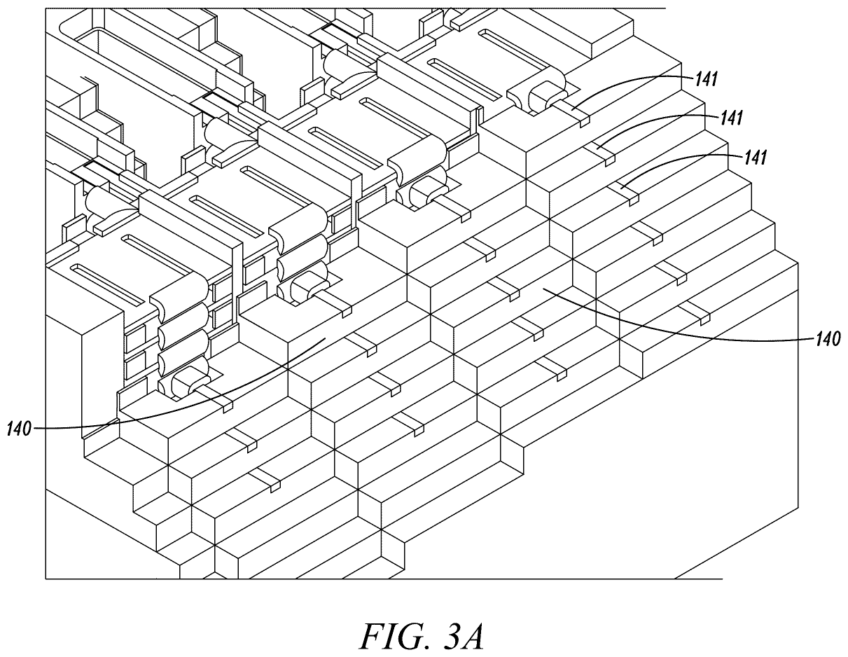

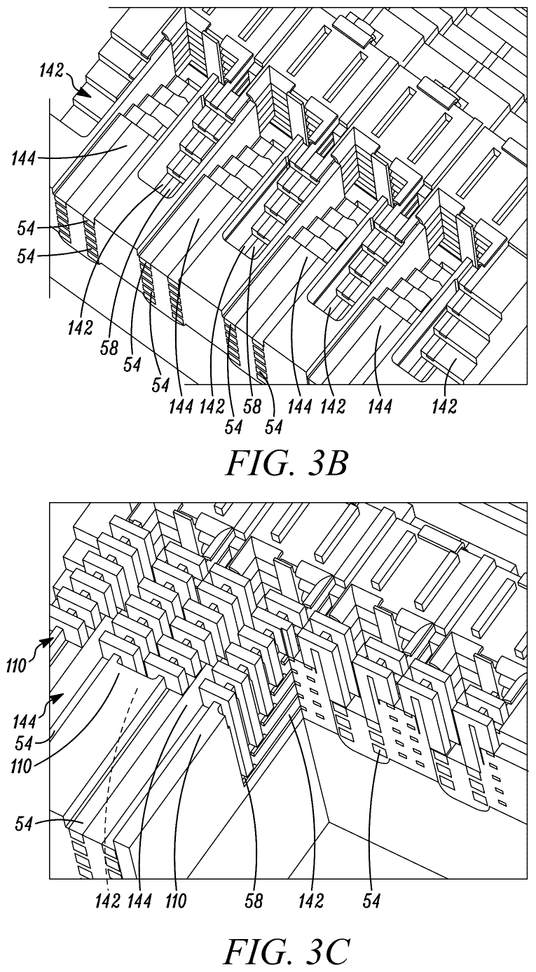

Referring now to FIGS. 1B and 1C, 3D DRAM integrated circuits according to the present disclosure rotate the 2D DRAM memory cell shown in FIG. 1A in two orthogonal directions. In FIG. 1B, the memory cell 50 of 2D DRAM of FIG. 1A is rotated 90° (e.g., the z-plane is rotated from vertical to horizontal) and then multiple memory cells 50 are stacked. However, the arrangement in FIG. 1B requires deep lateral etching and materials with different selectivity to etch chemistry that is used to enable differing lateral recesses.

In FIG. 1C, the memory cell 50 of 2D DRAM is rotated 90° in a second direction (e.g., the x-plane is rotated from vertical to horizontal). The capacitors 54 extend horizontally. As can be seen, etching can be performed vertically rather than laterally (with different etch rates). However, this arrangement makes it more difficult to form contacts to gates, drains and sources of the nanosheet transistors.

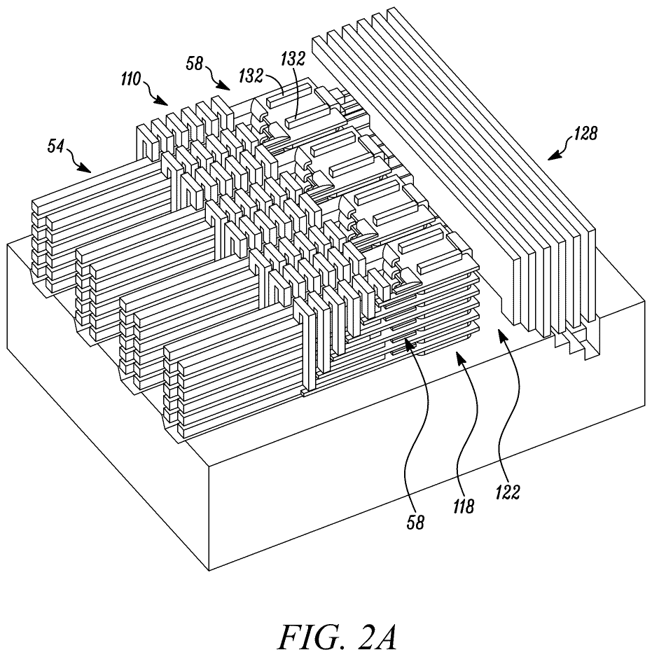

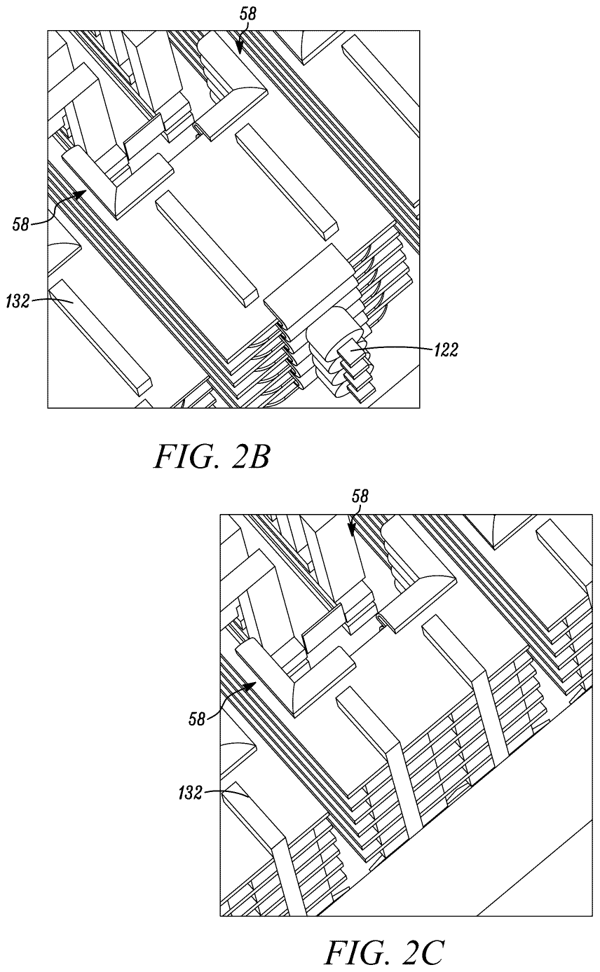

Referring now to FIGS. 2A to 2C, features of a 3D DRAM integrated circuit (IC) are shown. The 3D DRAM IC includes the capacitors 54 that extend horizontally and are connected by a bridge (or capacitor contacts 110) to the storage node contacts 58. The capacitor contacts 110 connect the capacitors 54 to the storage node contacts 58 using alternating up and down staircases as will be described further below. Bitlines 128 are connected by bitline contacts to drains 122 of nanosheet transistors 118 via a 2D staircase. Forksheet gates or wordlines 132 are connected to gates of the nanosheet transistors 118.

As can be appreciated, the 3D DRAM architecture includes a plurality of the 2D DRAM cells that have been rotated 90° twice and stacked. Plurality of alternating up and down staircases allow the capacitors 54 (now horizontal) to connect to the storage node contacts 58 and sources 56 of the nanosheet transistors. The storage node contacts 58 and the drains 122 are located on different sides of the nanosheet transistors 118.

Referring now to FIGS. 3A to 3C, a first staircase, a plurality of second staircases, a plurality of third staircases, and contacts in the 3D DRAM integrated circuit are shown. In FIG. 3A, a first staircase 140 allows the bitlines 128 to connect with the bitline contacts 141 that are connected to the drains 122 of the nanosheet transistors 118. In FIGS. 3B and 3C, a plurality of second staircases 144 provides connection locations to the capacitors 54. A plurality of third staircases 142 allows the capacitor contacts 110 to be connected to the capacitors 54 and the storage node contacts 58. In some examples, the highest capacitors are contacted to the lowest storage node contacts and vice versa.

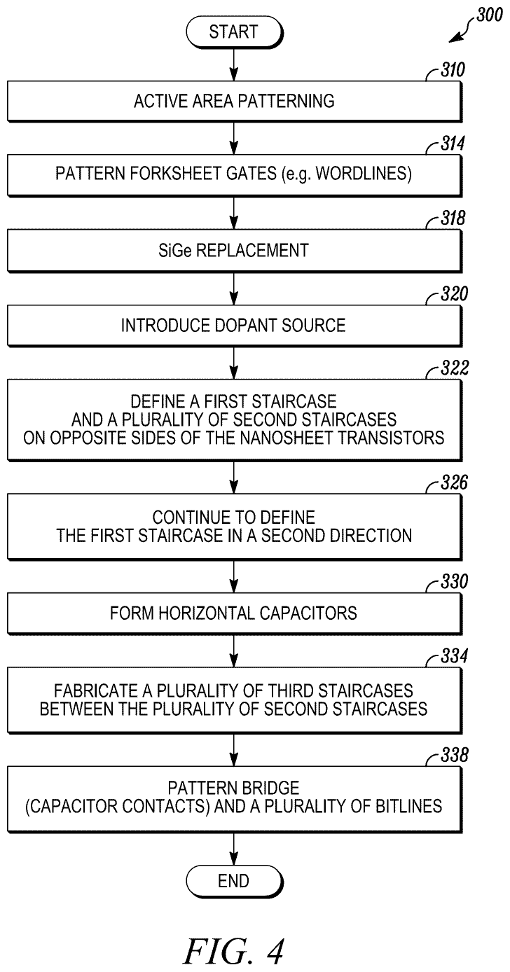

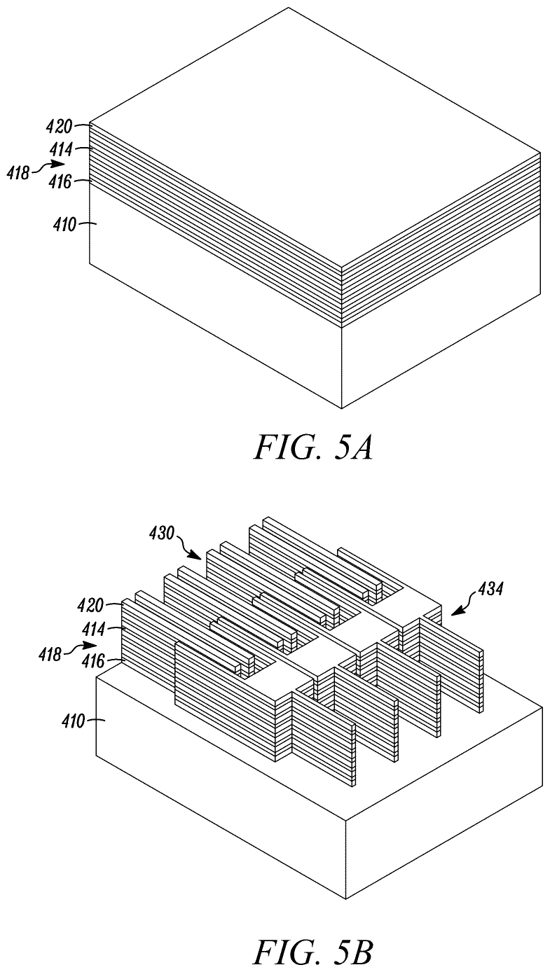

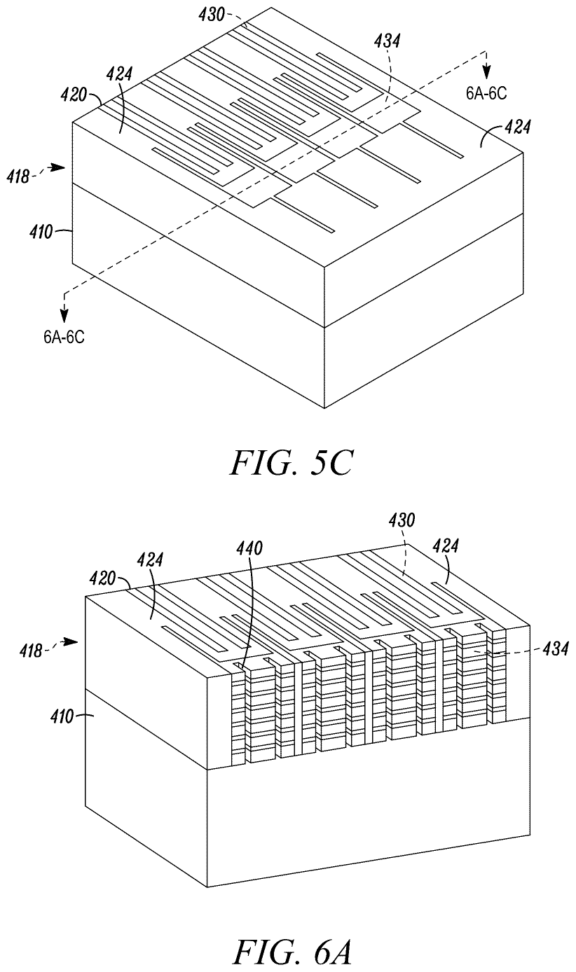

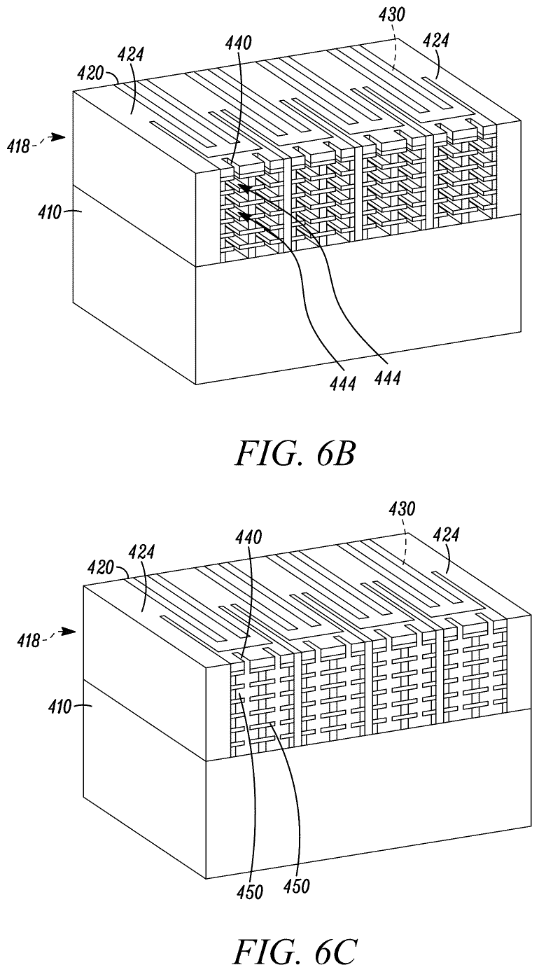

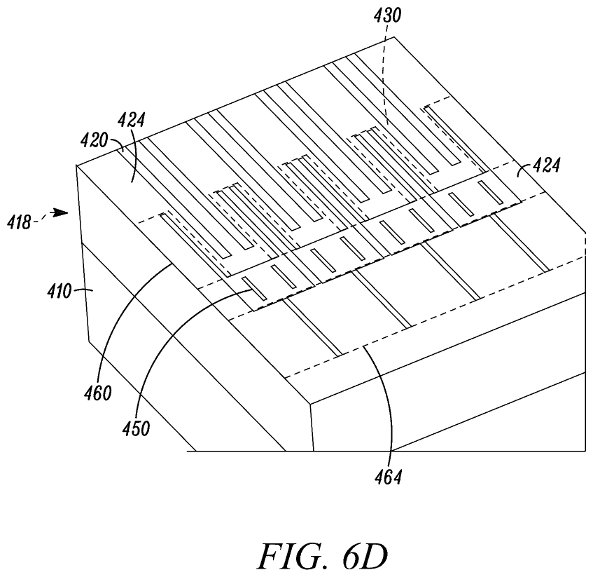

Referring now to FIG. 4, a method 300 for fabricating the 3D DRAM integrated circuit is shown. At 310, active area patterning and cladding is performed (e.g., as will be described below in FIGS. 5A to 5C). At 314, wordline (or forksheet gate) patterning is performed (e.g., an example is described below in FIGS. 6A to 6D).

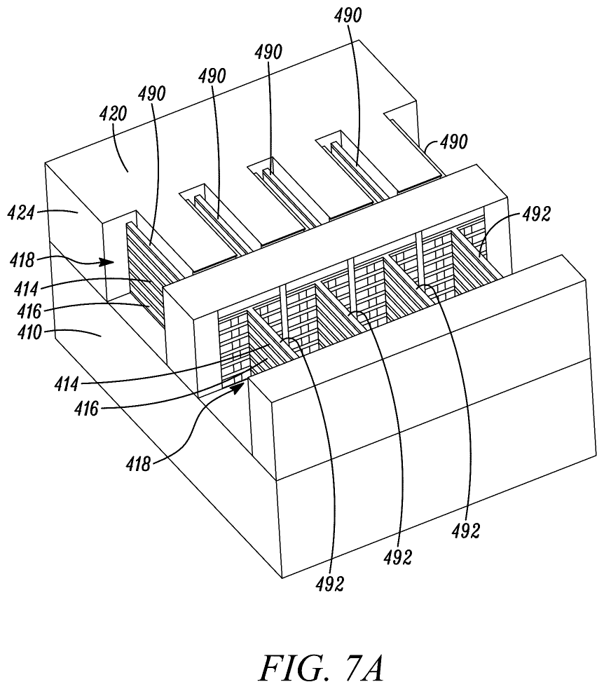

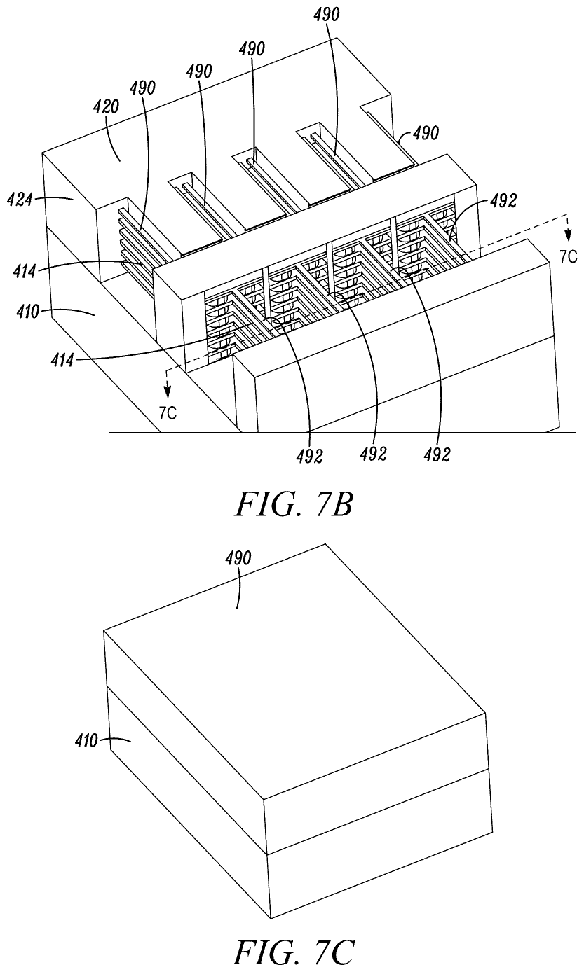

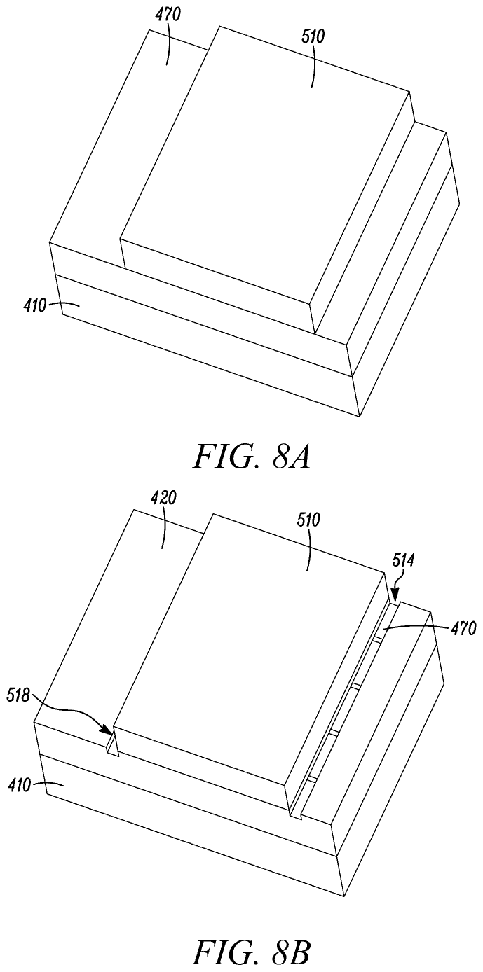

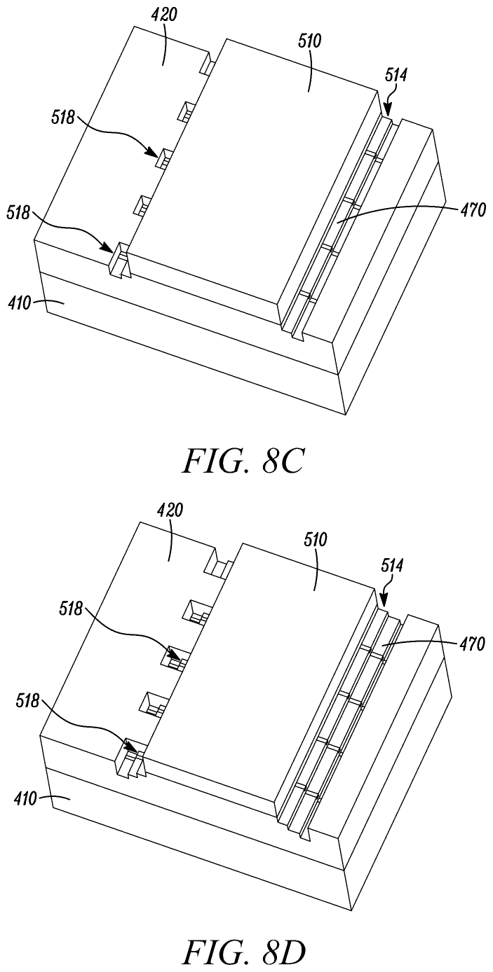

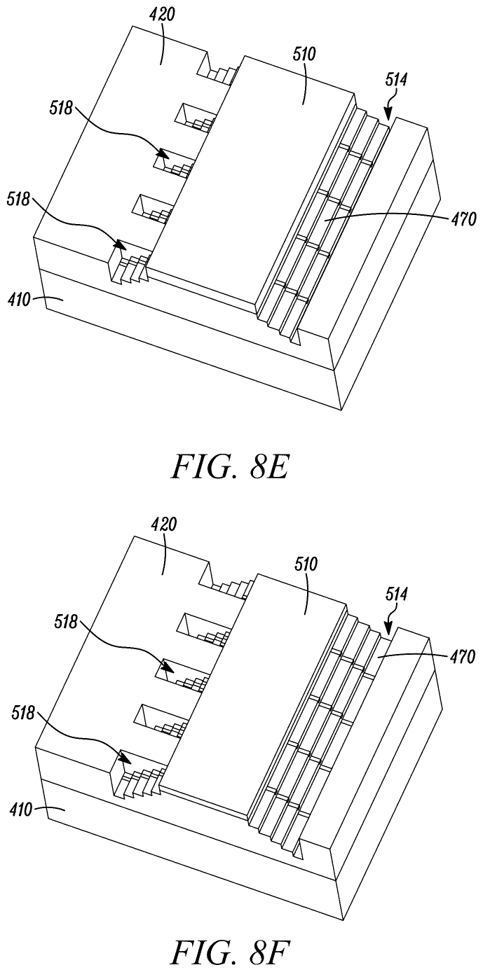

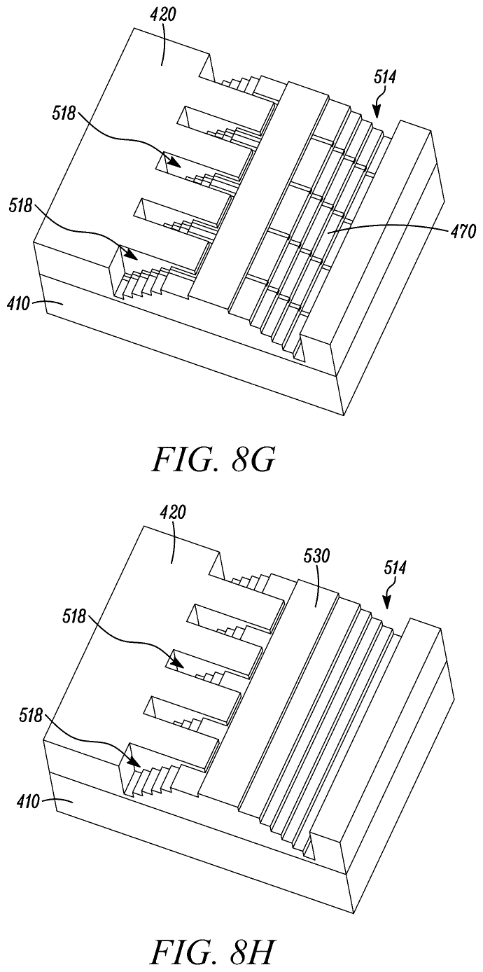

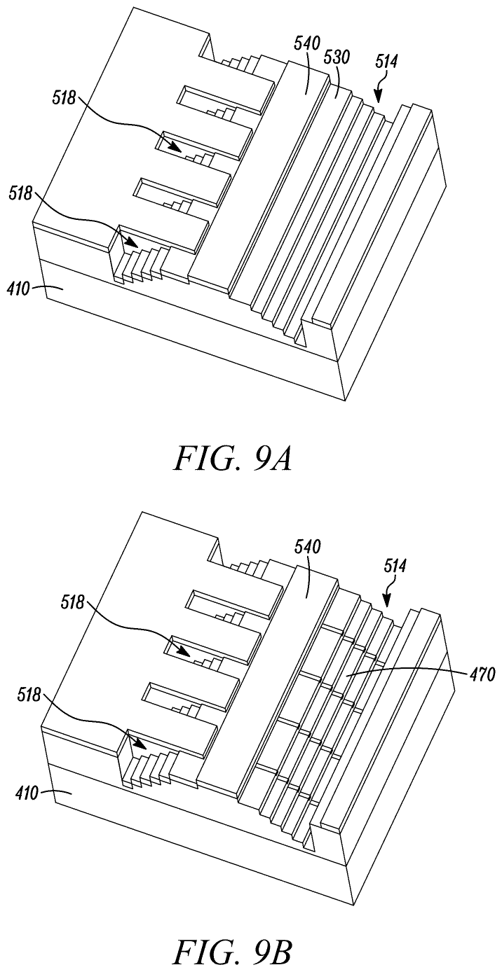

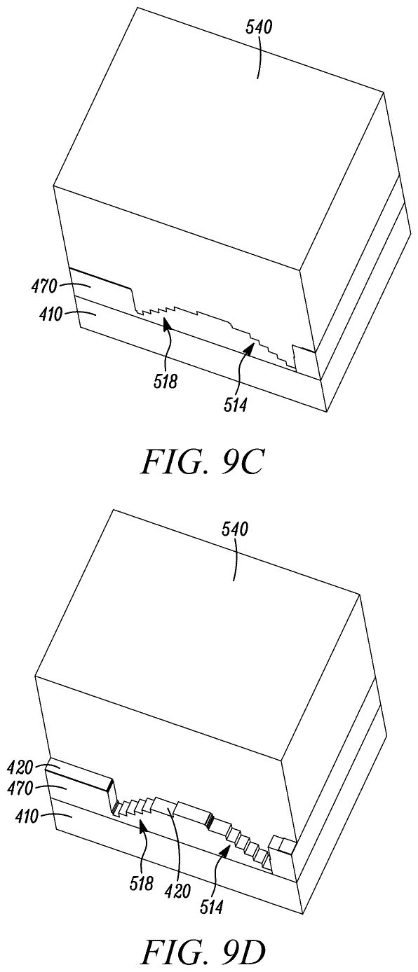

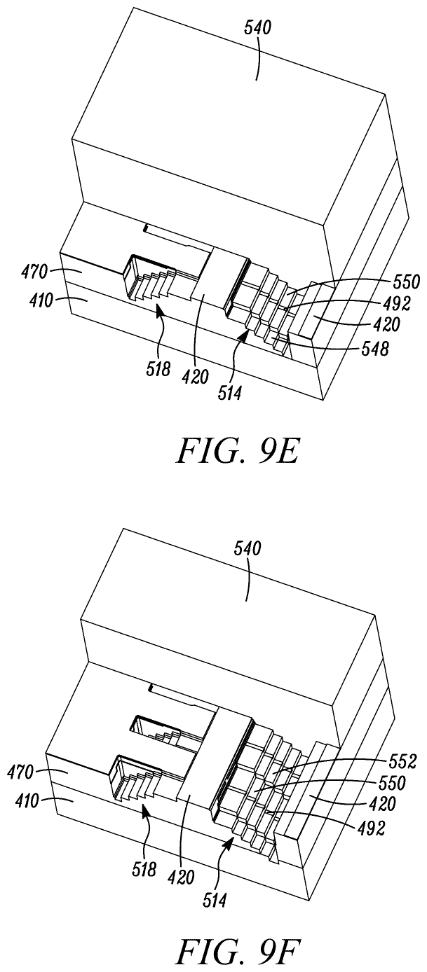

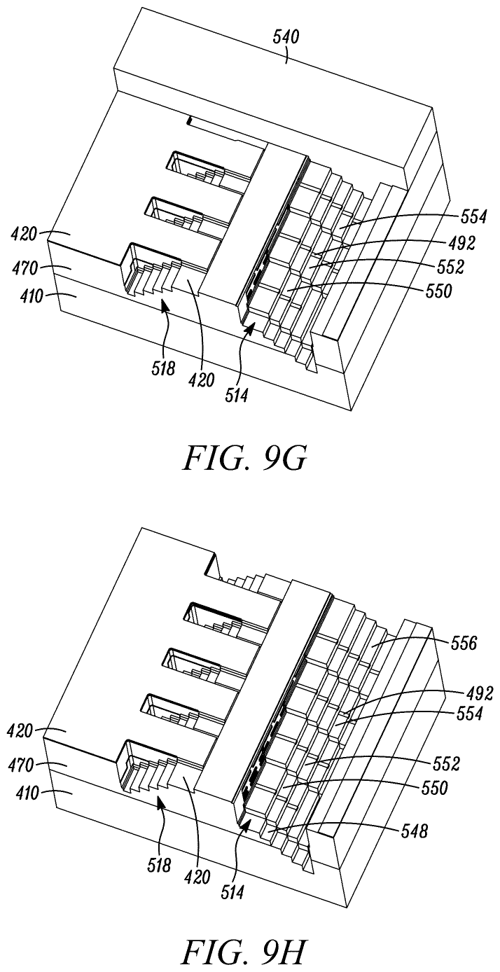

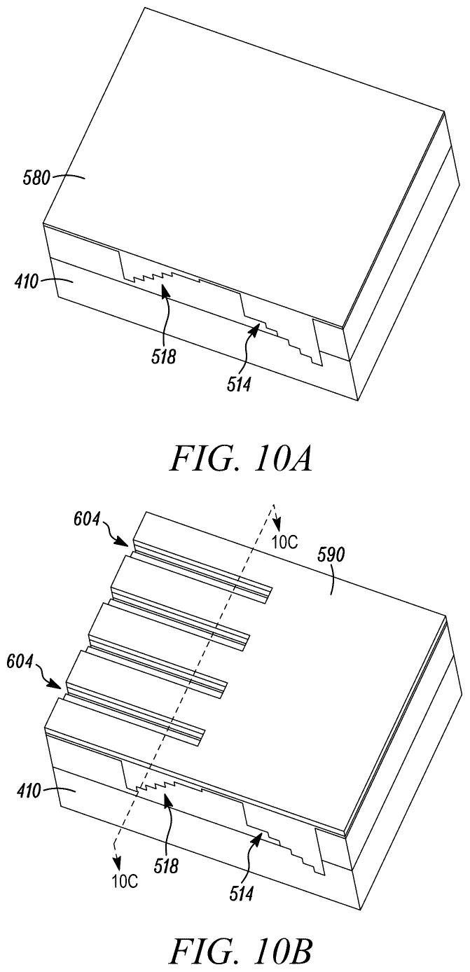

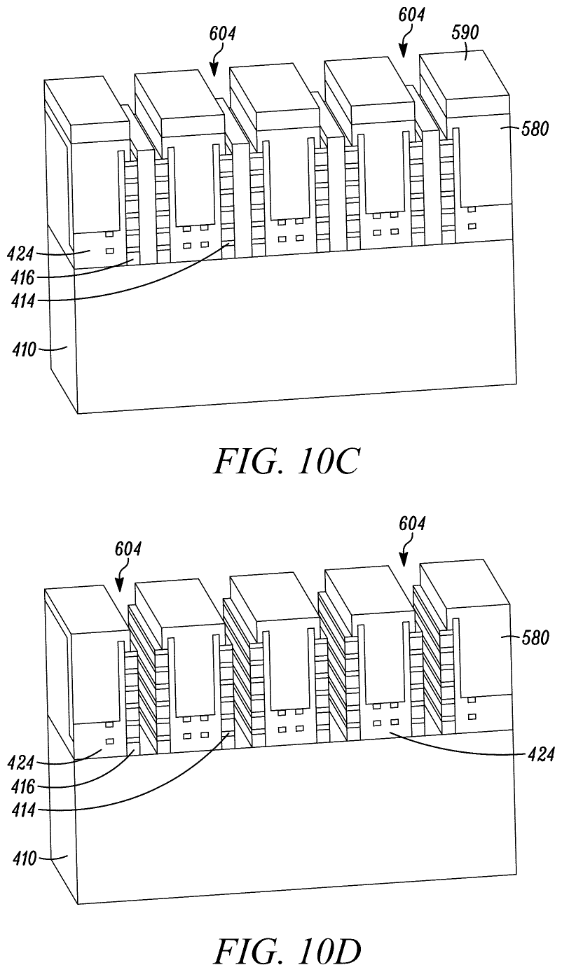

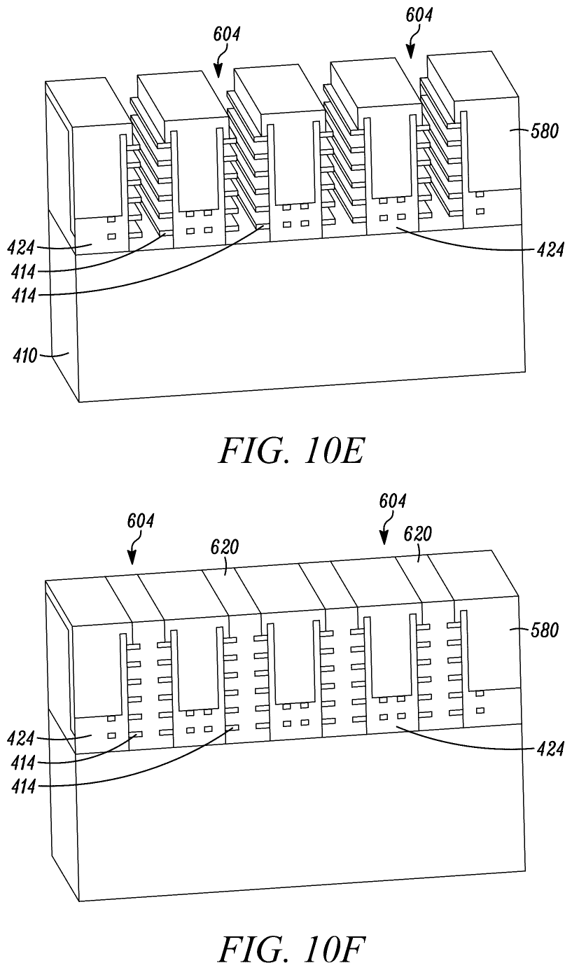

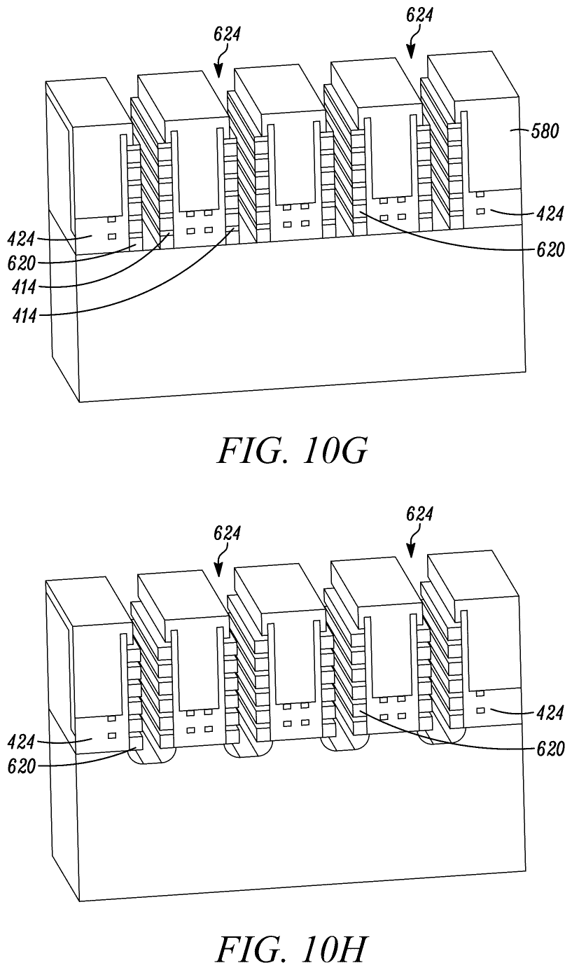

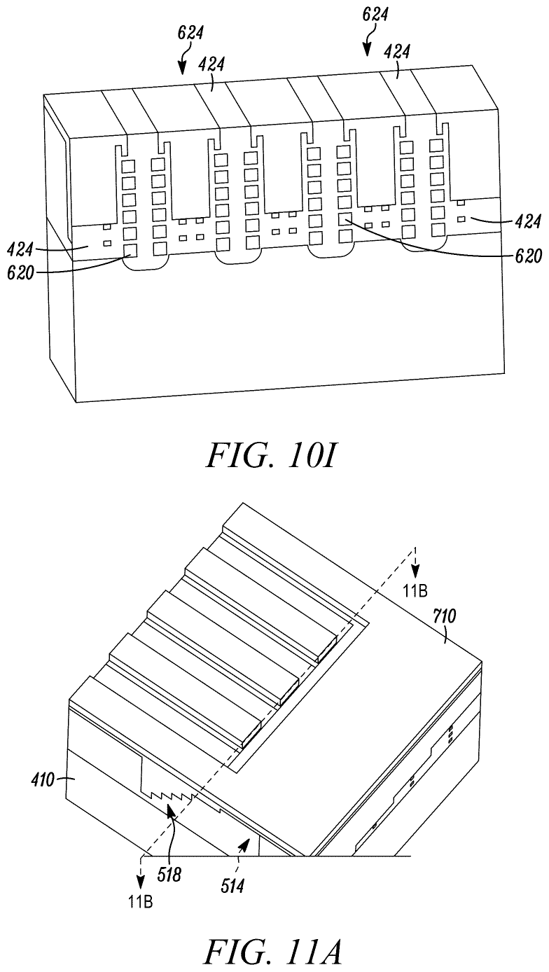

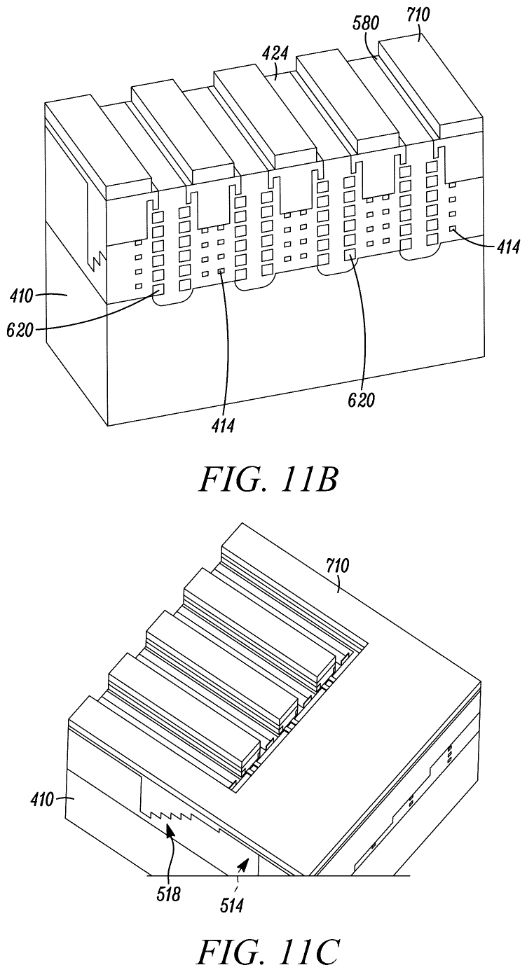

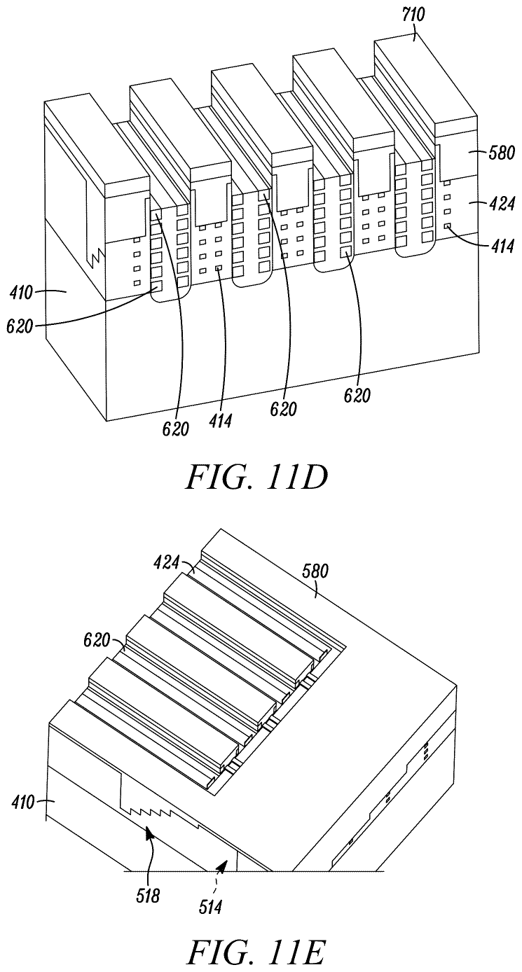

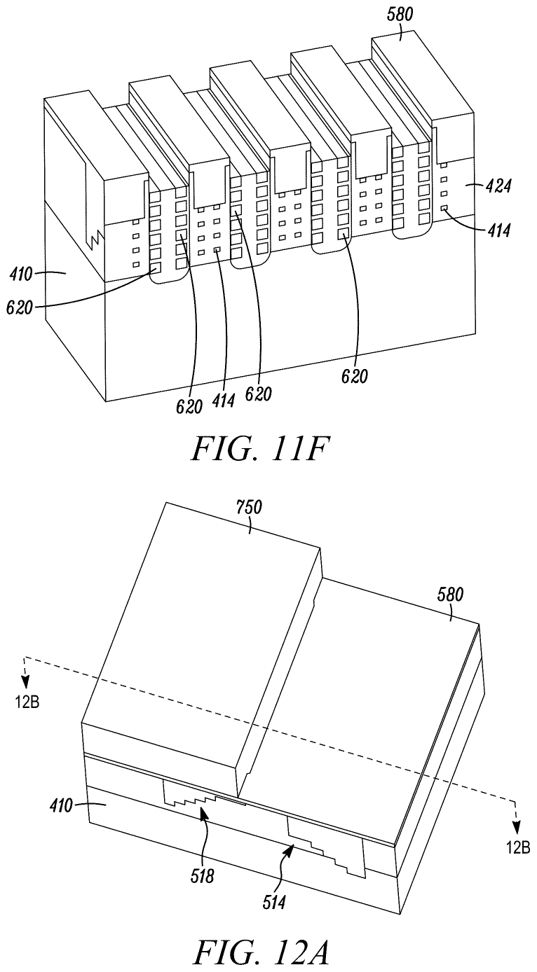

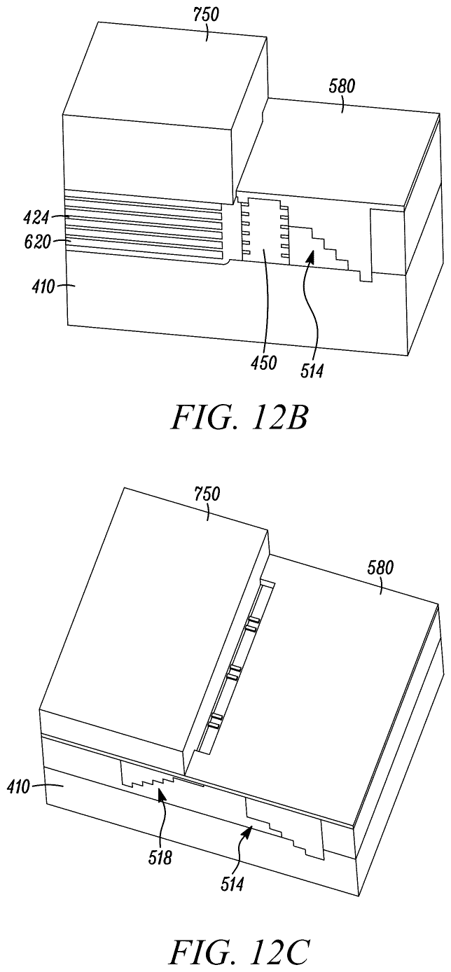

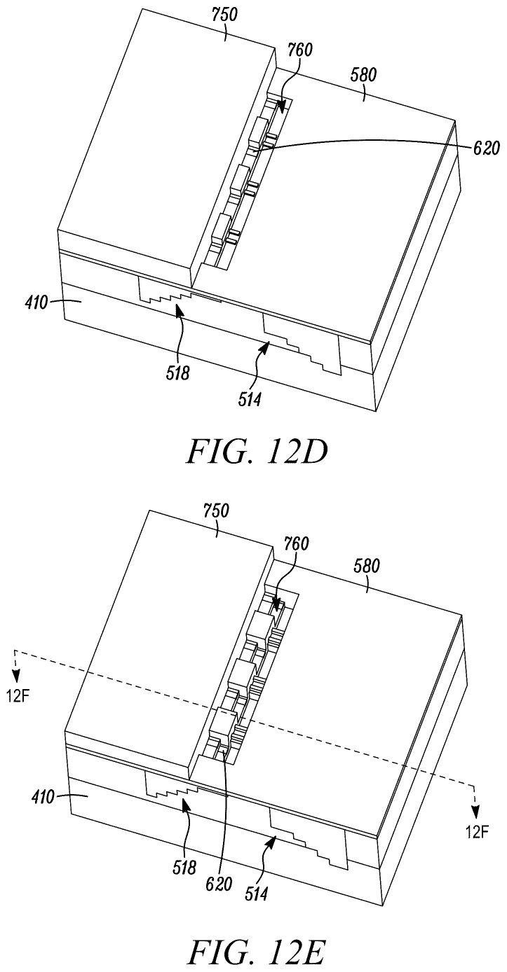

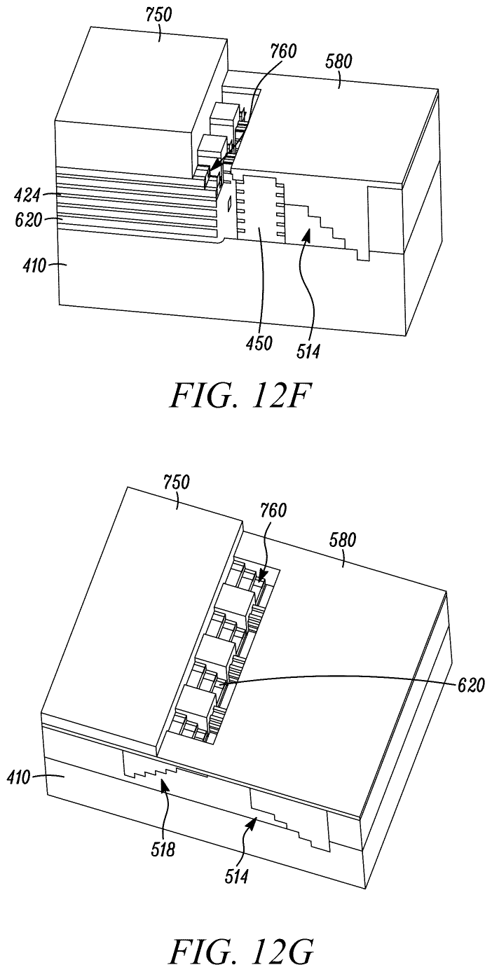

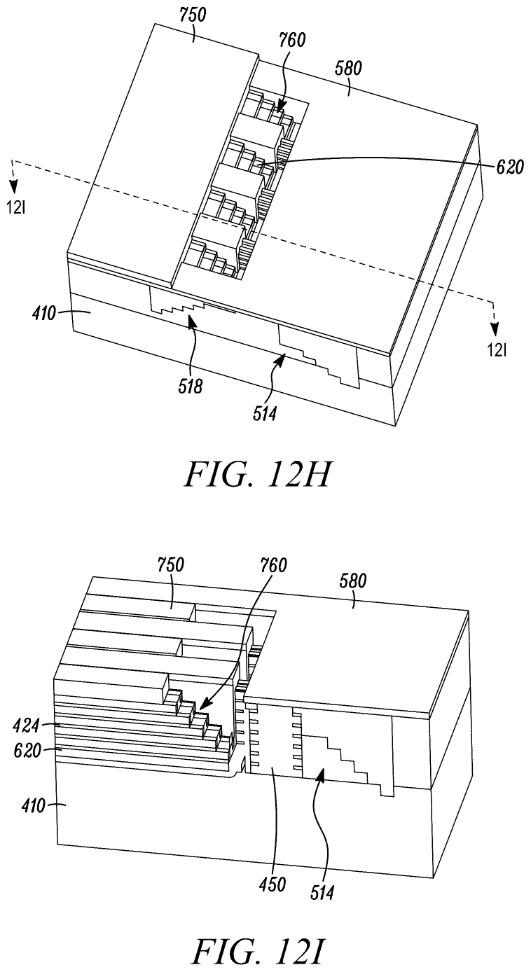

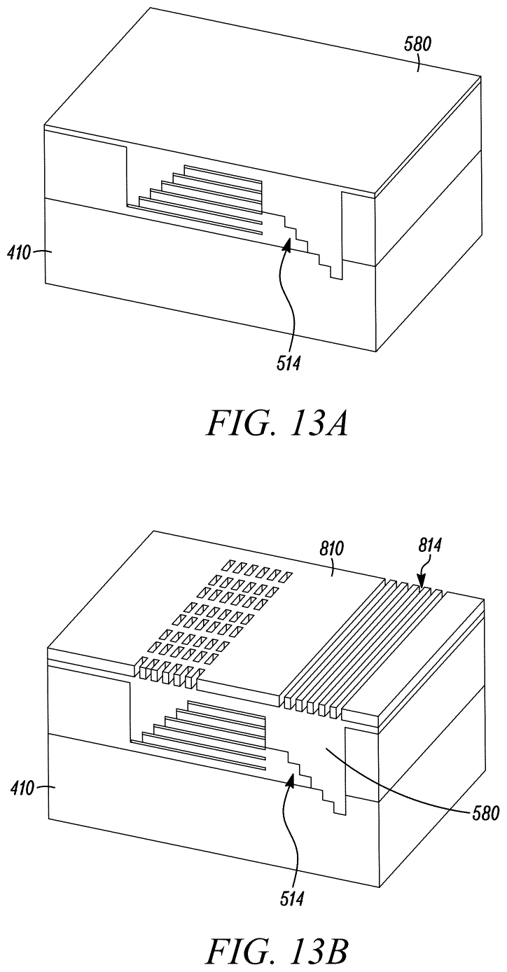

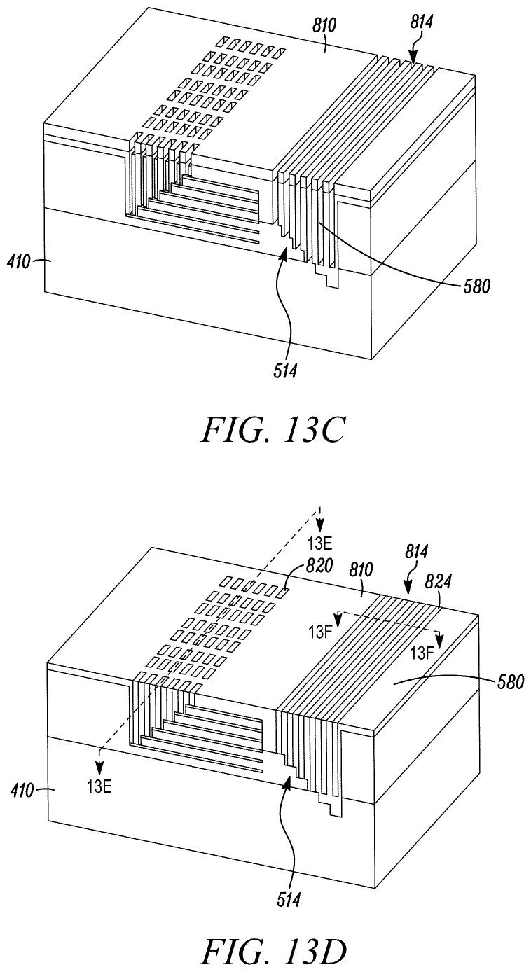

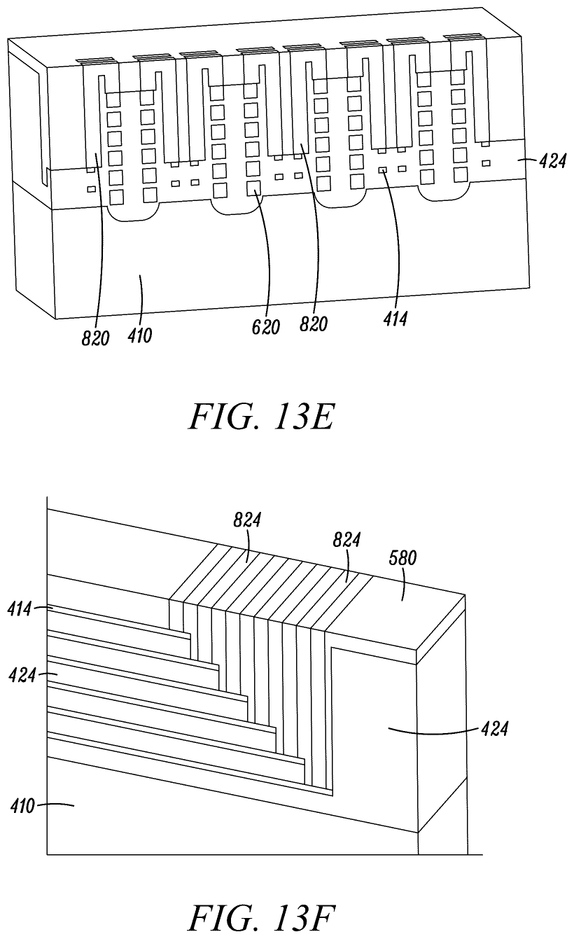

At 318, SiGe replacement is performed (e.g., an example is described below in FIGS. 7A to 7D). At 320, a dopant source performs doping of portions of the nanosheet transistors as needed. At 322, a first staircase is defined in a first direction and the plurality of second staircases is defined (e.g., an example is described below in FIGS. 8A to 8H). At 326, the first staircase is further defined in a second direction orthogonal to the first direction (e.g., an example is described below in FIGS. 9A to 9H). At 330, horizontal capacitors are formed (e.g., an example is described below in FIGS. 10A to 10I). At 334, a plurality of third staircases is defined between the plurality of second staircases (e.g., an example is described below in FIGS. 11A to 12G). At 338, a bridge (capacitor contacts) and bitlines are defined (e.g., an example is described below in FIGS. 13A to 13F).

Referring now to FIGS. 5A to 5C, active area patterning and deposition of an insulating layer are shown. In FIG. 5A, alternating silicon (Si) layers 414 and silicon germanium (SiGe) layers 416, respectively, (collectively alternating Si/SiGe layers 418) are deposited on a Si substrate 410. The silicon germanium (SiGe) layers 416 act as sacrificial layers. An insulating layer 420 (e.g., silicon nitride (Si₃N₄)) is deposited on a last Si layer of the alternating Si/SiGe layers 418.

In FIG. 5B, the insulating layer 420 and the alternating Si/SiGe layers 418 are patterned into a horizontal capacitor shape 430 and a forksheet shape 434 using lithography and one or more etching steps. In FIG. 5C, an oxide layer 424 (e.g., such as SiO₂) is deposited around the insulating layer 420 and the alternating Si/SiGe layers 418 after patterning.

Referring now to FIGS. 6A to 6D, wordline (or forksheet gate) patterning is shown. FIGS. 6A to 6C are shown as cross sections of the memory cells in FIG. 5C for illustration purposes. In FIG. 6A, vertical gate trenches 440 are created in the insulating layer 420 and the alternating Si/SiGe layers 418 using lithography and etching steps.

In FIG. 6B, selective lateral etching of the SiGe layers 416 in the alternating Si/SiGe layers 418 is performed through the vertical gate trenches 440 to create lateral openings 444. The lateral etching is selective in that substantially more of the SiGe layers 416 is etched relative to the silicon layers 414 in the alternating Si/SiGe layers 418.

In FIG. 6C, gate metal 450 (e.g., tungsten W)) for the wordlines is deposited in the lateral openings 444. In FIG. 6D, polishing such as chemical mechanical polishing (CMP) may be performed after deposition.

Referring now to FIGS. 7A to 7C, sacrificial SiGe replacement by dielectric is shown. In FIG. 7A, etching is performed to open the storage node contacts 490 and drain contacts 492 (corresponding to dotted lines 460 and 464, respectively, in FIG. 6D). In FIG. 7B, lateral etch recessing is performed to remove the SiGe layers 416 between the silicon layers 414 at the storage node contacts 490 and drain contacts 492. In FIG. 7C, deposition of oxide 470 is performed.

Referring now to FIGS. 8A to 8H, formation of a first staircase on one side of the nanosheet transistors and a plurality of second staircases on the other side of the nanosheet transistors is shown using resist patterning and an etch/resist trim loop. In FIG. 8A, a resist layer 510 is deposited on the substrate. Successive etching of the nitride and oxide layers is performed in FIGS. 8B to 8G to expose steps of the first staircase (at this point, the steps of the first staircase descend in a first direction) and steps of the plurality of second staircases. In FIG. 8B, a selected portion of the resist layer 510, the insulating layer 420, and the oxide layer 424 is etched to expose a first step of a first staircase 514 and first steps of a plurality of second staircases 518 (located on opposite sides of the nanosheet transistors). The plurality of second staircases 518 are spaced apart in a direction transverse to an ascending/descending direction.

In FIGS. 8C to 8G, selected portions of the resist layer 510, the insulating layer 420, and the oxide layer 424 are successively etched and additional steps of the first staircase 514 and additional steps of the plurality of second staircases 518 are defined. After a final step of the first staircase 514 and the plurality of second staircases 518 are defined in FIG. 8G, a nitride layer is deposited in FIG. 8H to cover the first staircase 514 and the plurality of second staircases 518. As can be seen, the first staircase 514 and the plurality of second staircases 518 descend in a direction away from the nanosheet transistors.

Referring now to FIGS. 9A to 9H, further processing of the steps of the first staircase 514 is shown. More particularly, the steps of the first staircase 514 are further etched to descend in a second direction orthogonal to the first direction (such that the first staircase is a 2D staircase). In FIG. 9A, a resist layer 540 is patterned and deposited on the nitride layer 530 in regions other than the first staircase 514. In FIG. 9B, the nitride layer 530 is removed over the first staircase 514. In FIG. 9C, a resist layer 540 is deposited. In FIG. 9D, patterning and etching of the resist layer 540 is performed to define steps 548 of the first staircase 514 in the second direction.

In FIG. 9E, etching of the resist layer 540 is performed to define steps 550 of the first staircase 514. In FIG. 9F, patterning and etching of the resist layer 540 is performed to define steps 552 of the first staircase 514. In FIG. 9G, patterning and etching of the resist layer 540 is performed to define steps 554 of the first staircase 514 (and to expose drain contacts 492). In FIG. 9H, patterning and etching of the resist layer 540 is performed to define steps 554 of the first staircase 514. As can be seen in FIG. 9H, the steps 548, 550, 552, 554 and 556 transition downwardly in first and second orthogonal directions (e.g., x and y directions).

Referring now to FIGS. 10A to 10I, horizontal capacitor formation is shown. In FIG. 10A, an insulating layer 580 (e.g., such as a nitride layer) is deposited and polished. In FIGS. 10B and 10C, an etch layer 590 is deposited on the insulating layer 580 and a trench opening 604 for the horizontal capacitors is etched. In FIG. 10D, the trench opening 604 is etched further to expose side surfaces of the silicon layers 414 and SiGe layers 416. In FIG. 10E, the SiGe layers 416 are laterally etched and removed between the silicon layers 414. In FIG. 10F, capacitor material 620 (e.g., such as titanium nitride) is deposited to fill the trench opening 610 and polished.

In FIG. 10G, a trench 624 is etched. The steps in FIGS. 10B to 10F replaced the SiGe layers 416 with the capacitor material 620. In FIG. 10H, the silicon layers 414 are laterally etched between layers of the capacitor material 620. At 10I, an oxide layer 424 is deposited in the trench 624 and polished.

Referring now to FIGS. 11A to 12G, a plurality of third staircases is defined between (or interleaved between) the plurality of second staircases 518. In FIG. 11A, a resist layer 710 is deposited and patterned on the oxide layer 424 and the insulating layer 580 above the first staircases 514 and the plurality of second staircases 518. Openings in the resist layer 710 are formed by lithography and etching. In FIGS. 11C and 11D, the oxide layer 424 and the insulating layer 580 are etched to expose upper surfaces of pairs of the horizontal capacitors (e.g., the capacitor material 620). In FIGS. 11E and 11F, the resist layer 710 is removed.

In FIG. 12A to 12I, a resist pattern and an etch/resist trim loop are used to define the plurality of third staircases. In FIGS. 12A and 12B, a resist layer 750 is formed on a portion of the insulating layer 580 above the horizontal capacitors (e.g., the capacitor material 620) and areas above the plurality of the second staircase 518. In FIGS. 12C to 12G, the resist layer 750 is successively removed and steps of the plurality of third staircases 760 are successively etched. As can be seen, the plurality of third staircases 760 descends in a direction towards the nanosheet transistors and expose connection locations for the horizontal capacitors. The resist layer 750 is removed.

Referring now to FIGS. 13A to 13F, bridge and bitline processing is shown. In FIG. 13A, the insulating layer 580 is deposited and polished. In FIG. 13B, a resist layer 810 is deposited and a pattern 814 for bridge (or capacitor contacts) and bitlines (connecting to bitline or drain contacts) is created. In FIG. 13C, the bridge and bitlines are etched through the pattern 814. In FIG. 13D, metal is deposited to form the bridges (or capacitor contacts) 820 and the bitlines 824 and the resist layer 810 is removed. In FIGS. 13E and 13F, additional cross sections are shown.

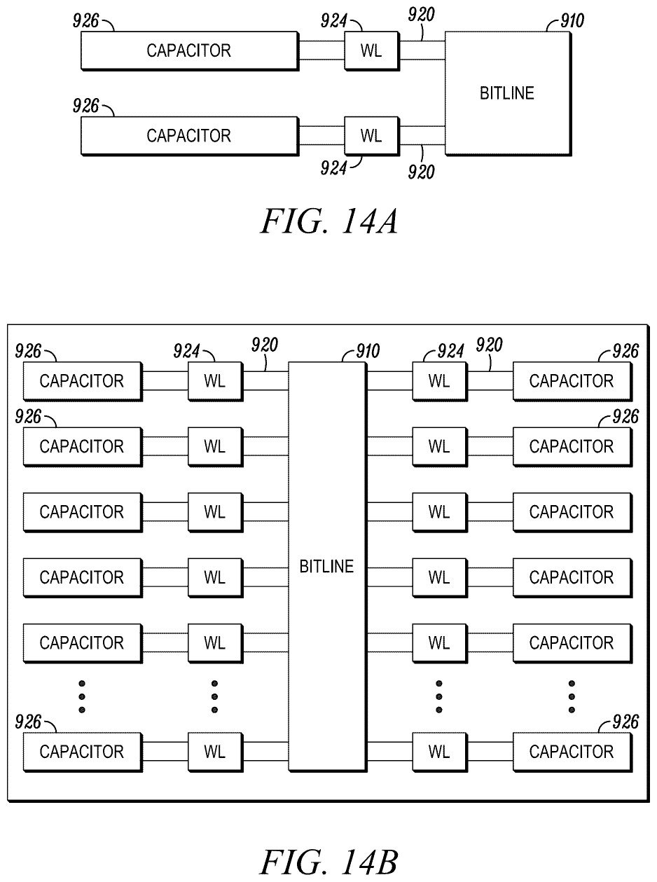

Referring now to FIGS. 14A and 14B, a portion of another example of a 3D DRAM is shown. As noted above, the bitlines are arranged on the opposite side of the nanosheet transistors and a gate forksheet design is used. Additional changes include using gate all around nanosheet transistors, wider capacitors, and an increased number of transistors per bitline. In FIG. 14A, a bitline 910 is shared by multiple transistors 920 and capacitors 926. The capacitors 926 are wider (as compared to prior designs). The capacitors 926 are connected to first sides of channels of the transistors 920. Wordlines 924 are connected around gate terminals of the transistors 920. The bitlines 910 are connected to second sides of channels of the transistors 920. In FIG. 14B, each of the bitlines 910 may be connected to a plurality of terminals of a plurality of transistors 920 symmetrically located on opposite sides thereof on multiple levels.

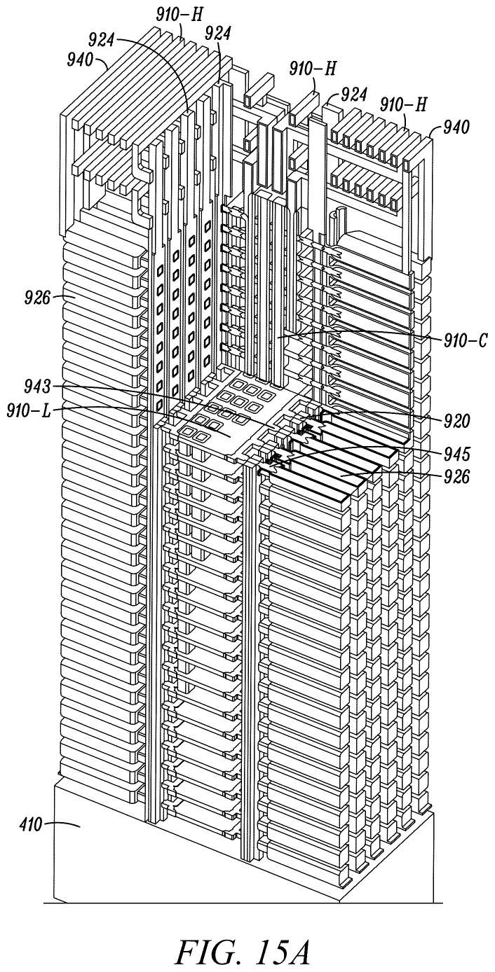

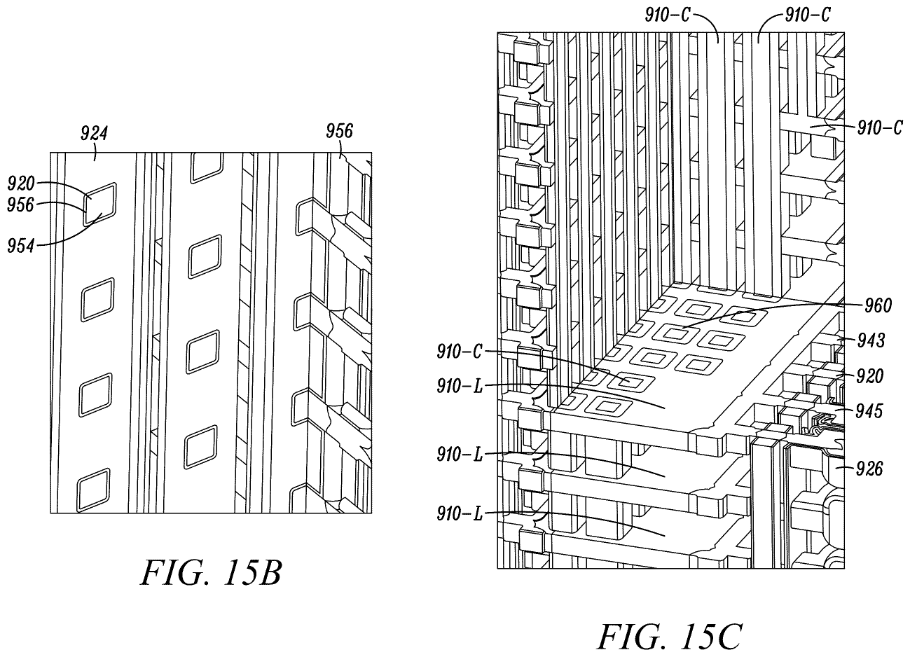

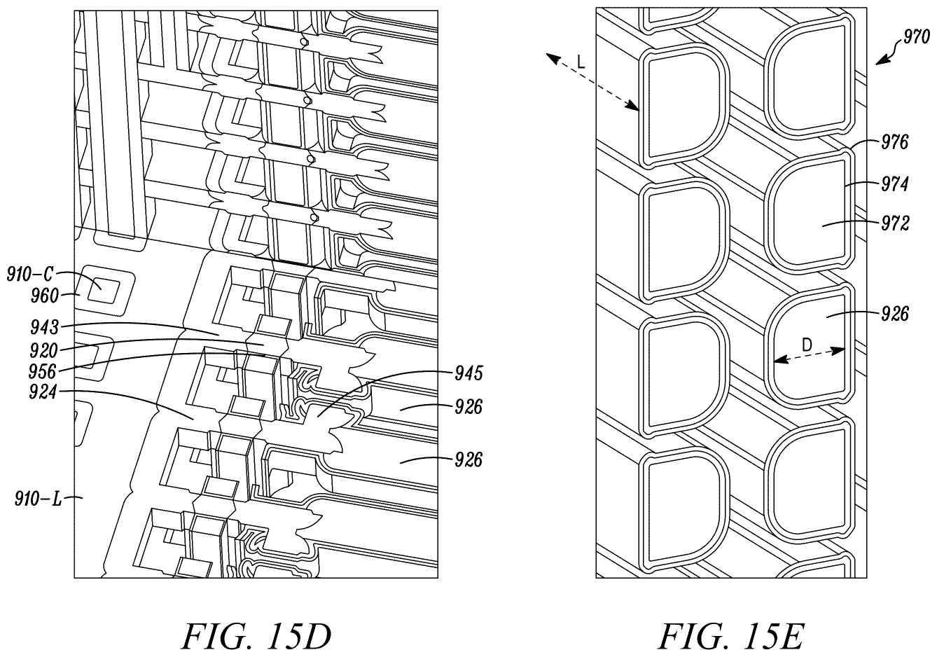

Referring now to FIG. 15A to 17B, additional features of the 3D DRAM are shown. In FIG. 15A, a stack of the transistors 920 include gates connected to the wordlines 924 that extend vertically. In FIG. 15B, a silicon channel 954 of a transistor 920 is shown in the gate metal. An isolator layer 956 (high k layer) is arranged between the silicon channel 954 of the transistor 920 and the gate metal (or the wordline 924). In FIGS. 15A and 15C, vertical bitline contacts 910-C extend to different elevations and connect to bitline layers 910-L extending in spaced parallel planes. In some examples, 28 layers of capacitors are used. In some examples, there are 28 layers of the capacitors 926, 6 in each row per unit cell on two sides of the unit cell (e.g., 28*6*2=336 transistors per unit cell).

In FIG. 15C, the vertical bitline contacts 910-C pass through insulated portions 960 of the bitline layers 910-L to prevent shorting and then connect to a corresponding one of the bitline layers 910-L. In some examples, the bitline layers 910-C are arranged between two rows of transistors as shown in FIG. 14B. In some examples, there are 28 bitline layers 910-L. Each of the bitline layers 910-L is pierced by bitline contacts 910-C connected to other bitline layers 910-L (contact is prevented by the insulated portions 960). In some examples, each bitline layers 910-L contacts 12 transistors and there is one bitline contact 910-C per bitline layer 910-L. Horizontal bitlines 910-H connect to the vertical bitline contacts 910-C, which are connected to the bitline layers 910-L.

In FIGS. 15A and 15D, multi-bridges 943 connect the bitline layer 910-L to first sides of channels of the transistors 920 and multi-bridges 945 connect second sides of channels of the transistors 920 to the capacitors 926. In some examples, a gate length is greater than 30 nm to avoid a short channel effect.

In FIG. 15E, the capacitors 926 may comprise an array 970 of metal-isolator-metal capacitors. For example, an inner metal layer 972 comprises a conductor such as titanium nitride (TiN), an isolator layer 974 comprises a material having a high dielectric constant, and an outer layer 976 comprising a conductor such as TiN. In some examples, the outer layer 976 is grounded by contacts 940 in FIG. 15A. In some examples, there are 28 layers of the capacitors 926, 6 rows per unit cell on two sides of the unit cell (e.g., 28*6*2=336 capacitors per unit cell).

The metal-isolator-metal capacitance increases when the length L of the capacitor 926 increases, the diameter d of the inner metal layer 972 increases, a thickness of the isolator decreases, and a dielectric constant of the isolator increases. In some examples, the capacitance of the metal-isolator-metal capacitor is greater than 5 femtofarads (fF) and the length L defines an acceptable footprint for the 3D DRAM.

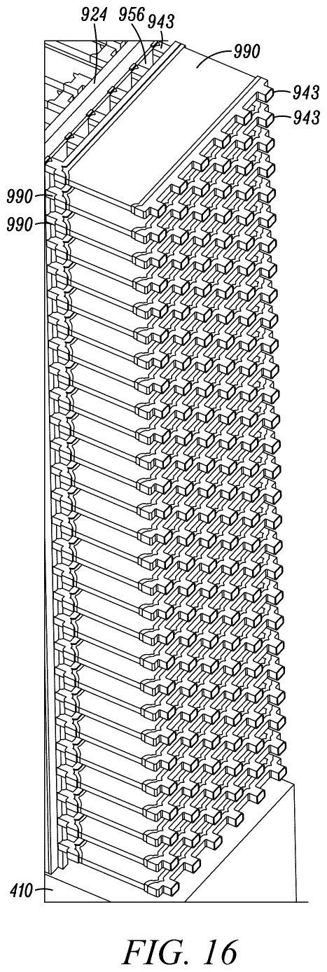

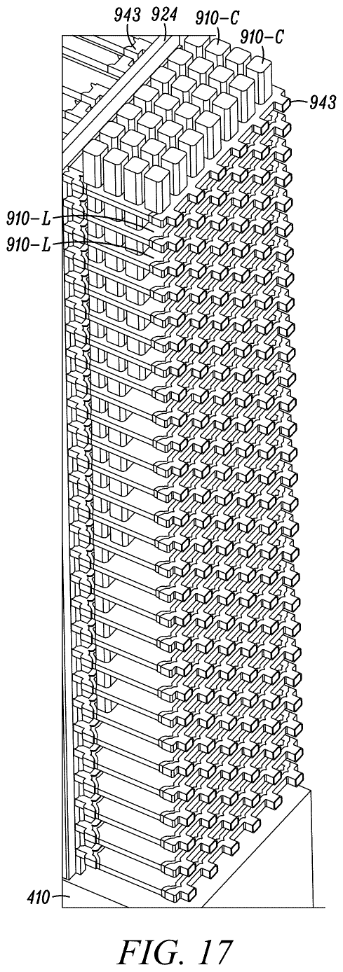

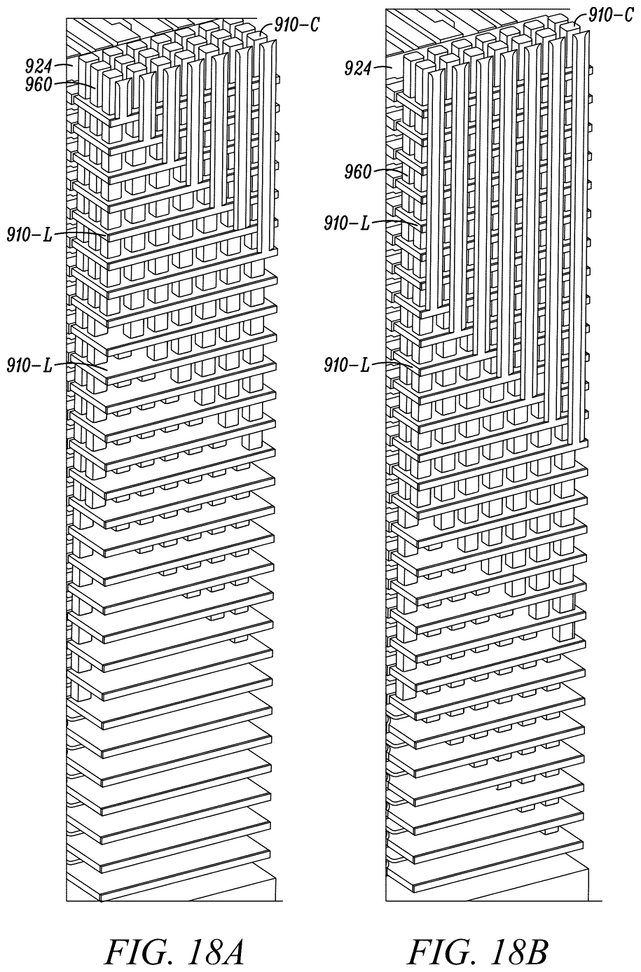

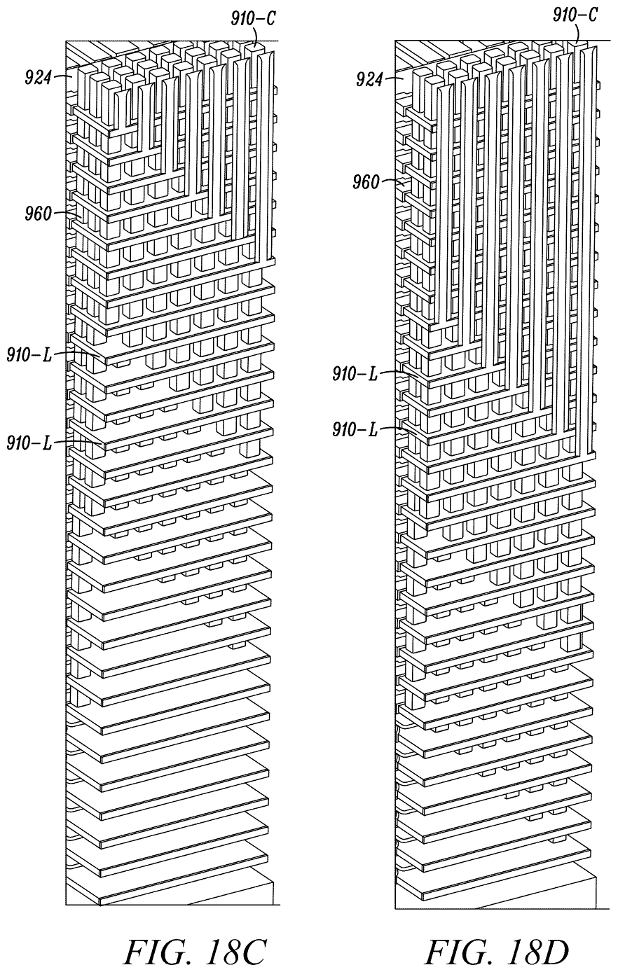

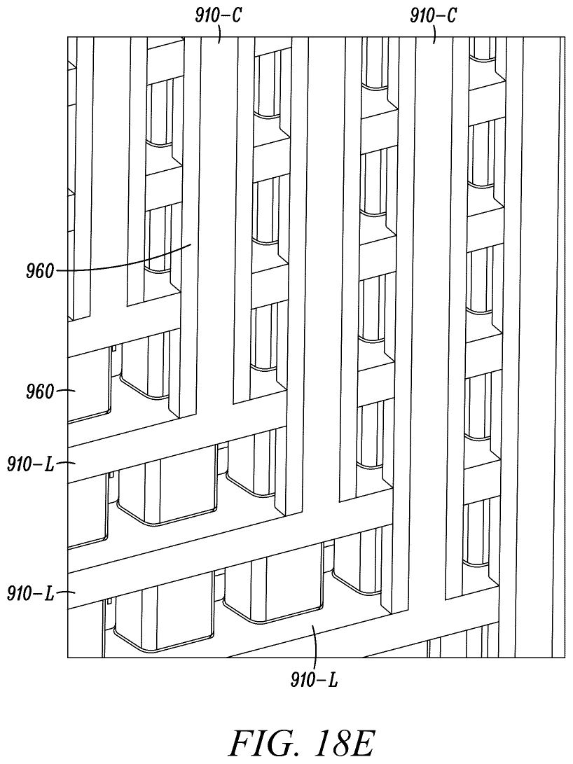

Referring now to FIGS. 16 to 18E, additional features of the 3D DRAM are shown. In FIG. 16, the multi-bridges 943, the transistors 920, the multi-bridges 945, and the capacitors 926 extend from opposite sides of a stack of sacrificial silicon layers 990 (replaced by the bitline layers 910-L). In FIGS. 17 to 18D, the sacrificial silicon layers 990 are perforated by two arrays of vias (corresponding to bitline contacts 910-C) landing at different elevations of the stack of sacrificial silicon layers 990. The silicon material in the sacrificial silicon layers 990 is replaced by conductor material through the vias to form to bitline contacts 910-C as will be described further below. In FIG. 18E, a bitline contact bank including the bitline contacts 910-C corresponds to a very dense area of the 3D DRAM architecture.

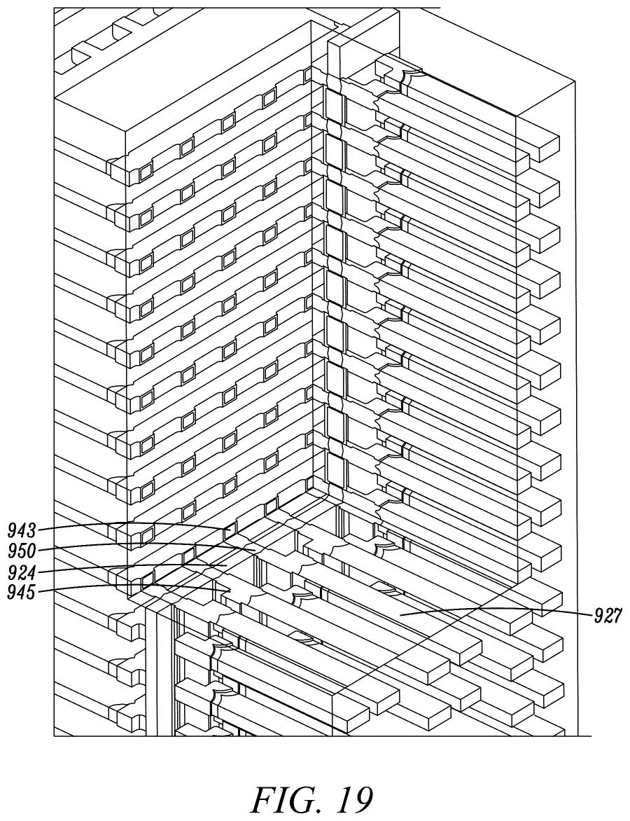

Referring now to FIG. 19, the multi-bridges 943 and 945 have multiple functions. The multi-bridges 943 allow the bitline layers 910-L to contact first sides of channels of the transistors 920. The multi-bridges 945 also allow second sides of channels of the transistors 920 to contact the capacitors 926. In addition, the multi-bridges 943 and 945 act as a silicon etch stop layer during replacement of silicon at 927 (in future locations of capacitors 926) during fabrication of the bitline contacts 910-C and the capacitors 926.

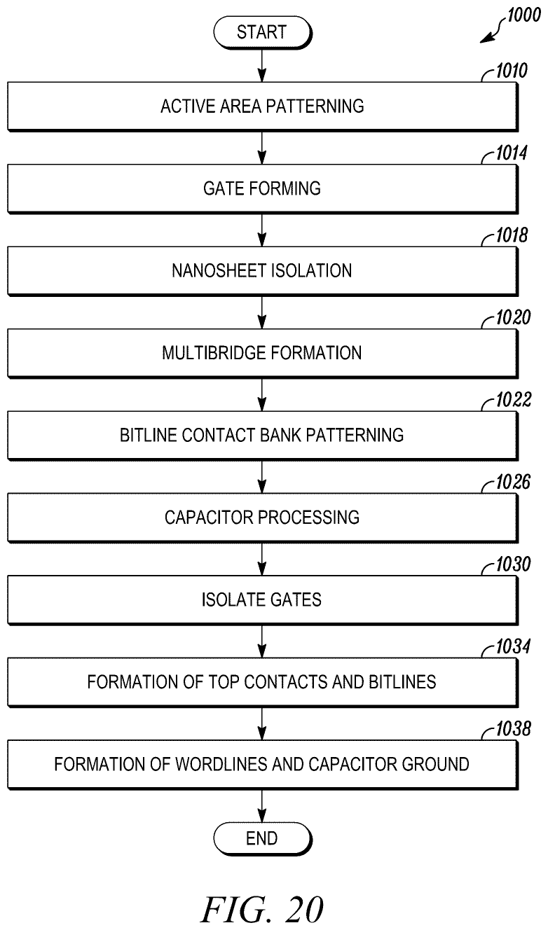

Referring now to FIG. 20, a method 1000 for fabricating the 3D DRAM in FIGS. 14 to 19 is shown. At 1010, patterning of the active area is performed. At 1014, the gates are formed. At 1018, isolation of the nanosheet transistors is performed. At 1020, the multi-bridges are formed. At 1022, patterning of the bitline contact bank is performed. At 1026, the capacitors are processed. At 1030, the gates are isolated. At 1034, formation of top contacts and bitlines is performed. At 1038, formation of wordlines and capacitor ground is performed.

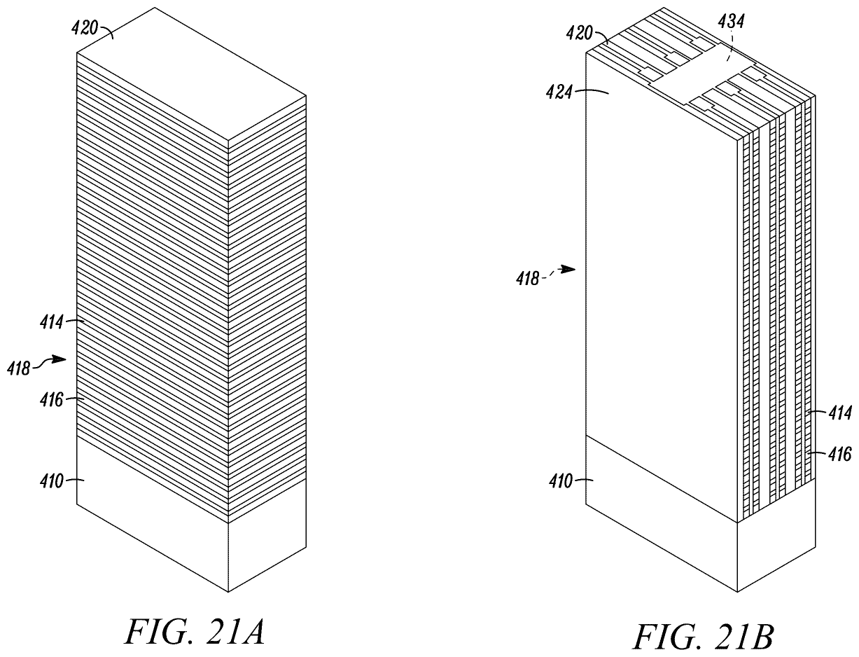

Referring now to FIGS. 21A and 21B, patterning of the active area is shown. In some examples, the silicon layers 414 and silicon germanium layers 416 are alternately deposited on a silicon substrate 410 and patterned in a manner similar to that shown and described above in FIGS. 5A to 5C.

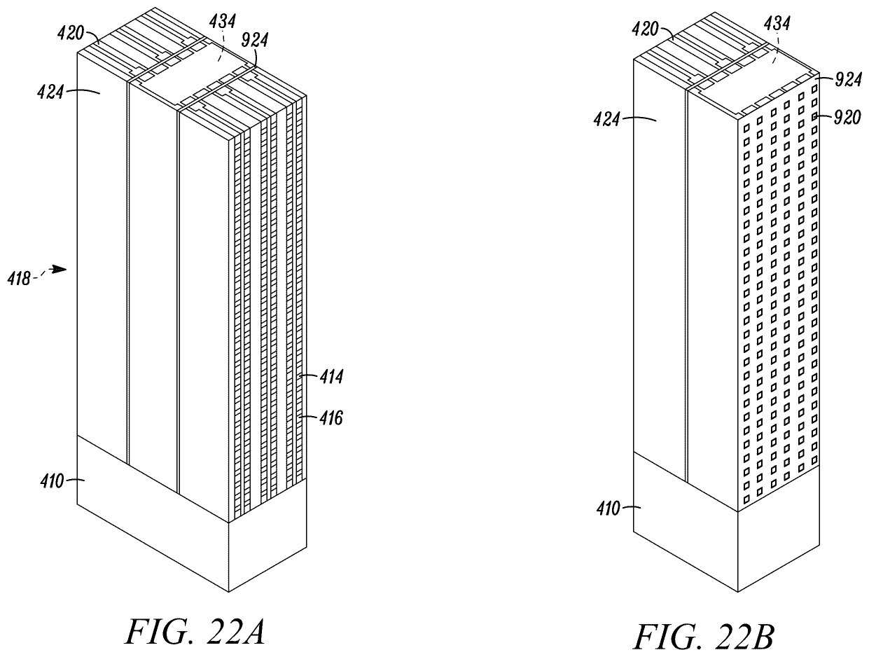

Referring now to FIGS. 22A and 22B, initial forming of the gates (the wordlines 924) is performed. Formation of the gates or wordlines 924 includes creating a trench, oxide etching and SiGe recessing, deposition of the isolator layer 956, and metal gate filling.

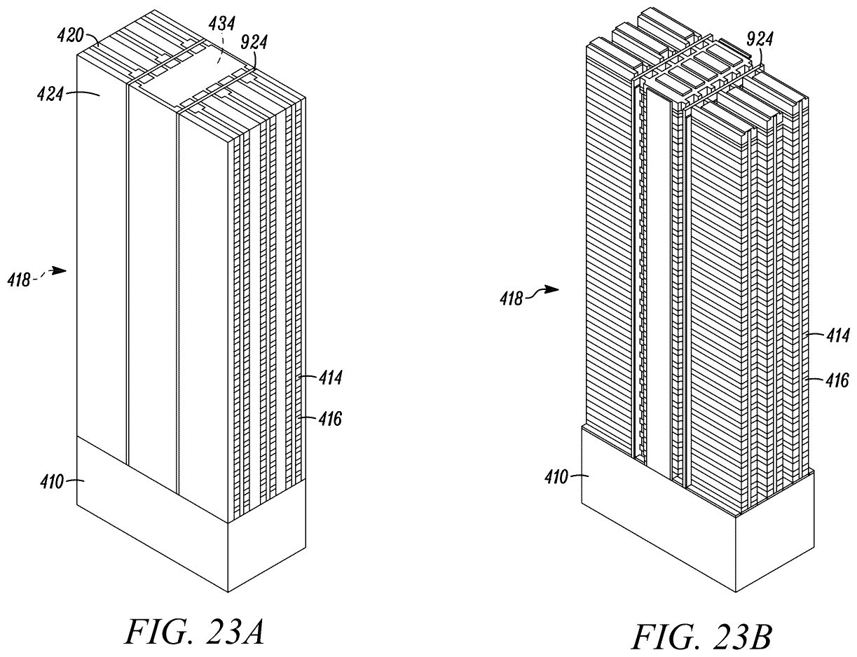

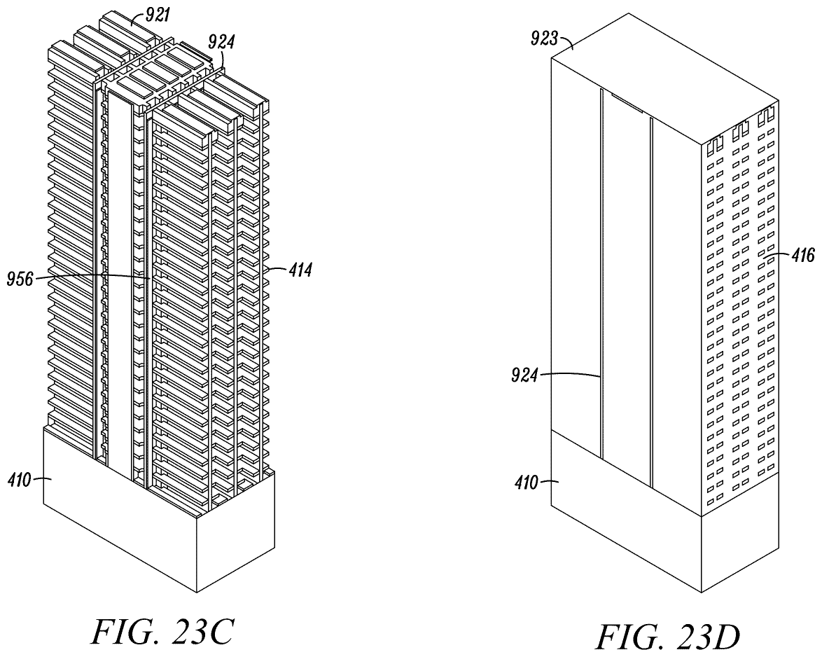

Referring now to FIGS. 23A and 23D, isolation of the transistors 920 is performed. Referring now to FIGS. 23A and 23B, oxide removal is performed. A mask 921 is deposited to maintain pillars providing mechanical integrity. At FIG. 23C, lateral etching of the silicon germanium layers 416 is performed. At 23D, oxide cladding 923 is deposited.

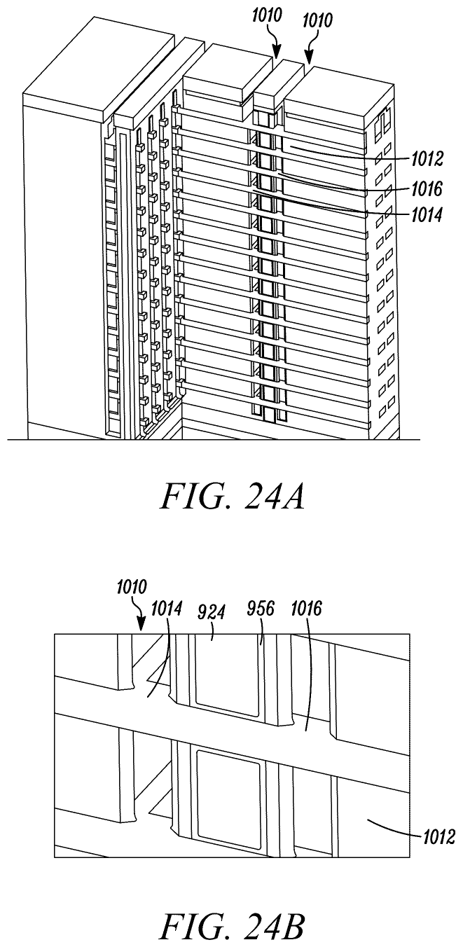

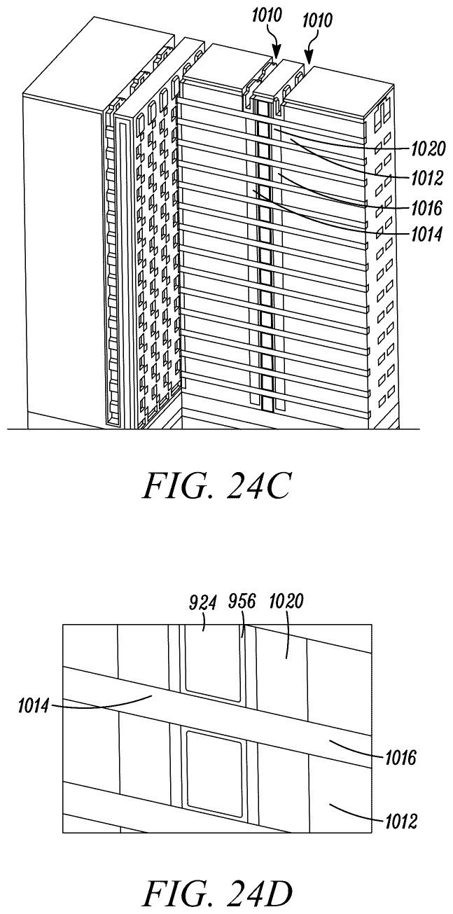

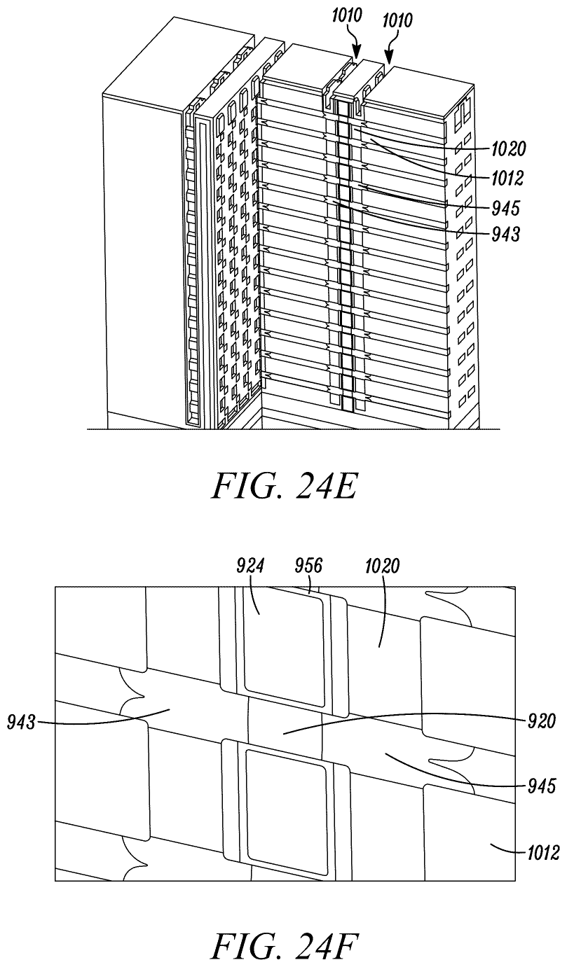

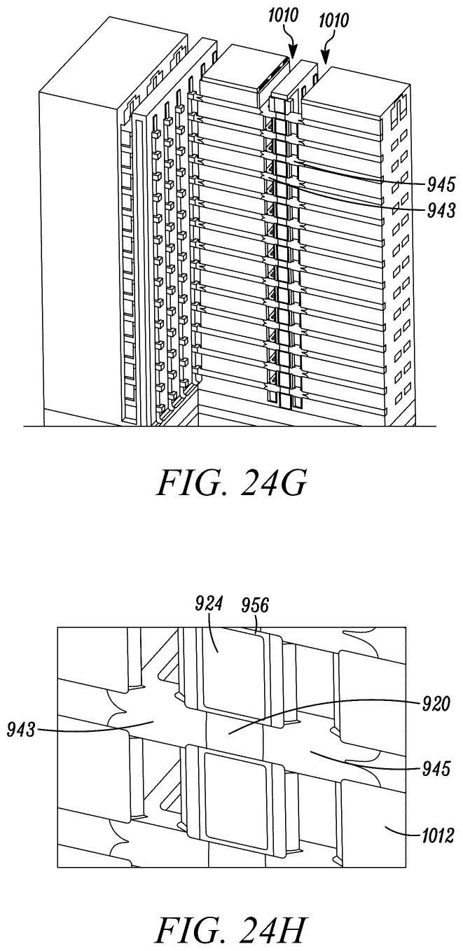

Referring now to FIGS. 24A to 24H, a first method for forming the multi-bridges 943 and 945 is shown. In FIGS. 24A and 24B, trenches 1010 are patterning on opposite sides of the channels of the transistors 920 and etching of oxide 1012 is performed (selective to oxide and leaving the silicon) to expose silicon bridges 1014 (eventually corresponding to multi-bridges 943 and 945, respectively) at different vertical levels. In FIGS. 24C and 24D, metal conformal deposition of a transition metal 1020 (e.g., cobalt (Co), nickel (Ni), etc.) is performed. Vapor phase doping may be used to bring dopants into silicon bridges and extensions. In FIGS. 24E and 24F, a salicide process (e.g., annealing) is performed to form an alloy of silicon and the transition metal and to create the multi-bridges 943 and 945. At 24G and 24H, removal of the transition metal 1020 (other than the alloy forming the multi-bridges 943 and 945) is performed.

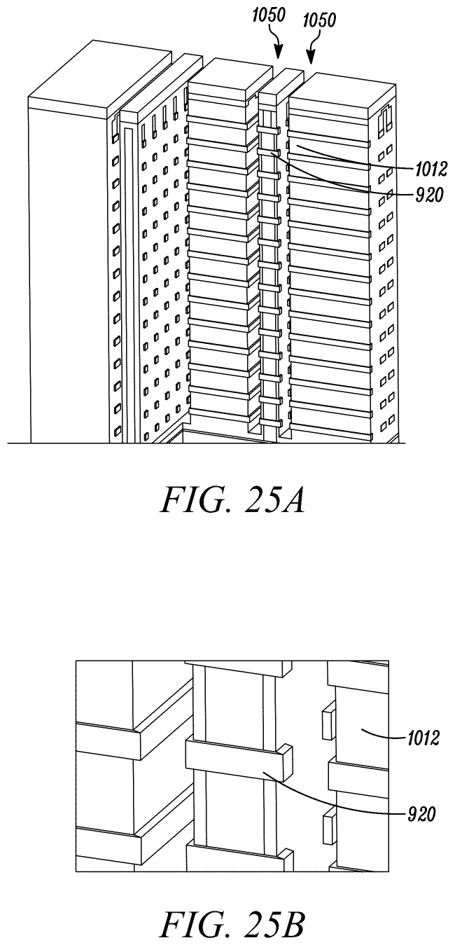

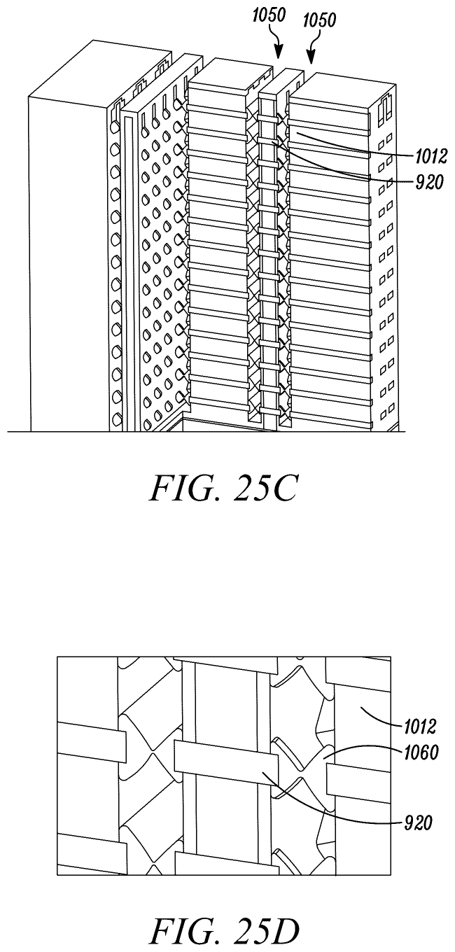

Referring now to FIGS. 25A to 25C, a second method for forming the multi-bridges 943 and 945 is shown. In FIG. 25A, trenches 1050 are patterned on opposite sides of channels of the transistors 920. Etching of the oxide 1012 and silicon in the trenches 1050 is performed. In FIG. 25B, selective deposition of a conductor 1060 (e.g., in-situ doped SiGe epitaxy) onto the silicon with merging fronts is used to form the multi-bridges 943 and 945. In some examples, when SiGe epitaxy is used, capacitor lines are 100 oriented to allow faster lateral growth (as compared to horizontal growth between transistors 920 or between sacrificial silicon in bitline layer or capacitor locations).

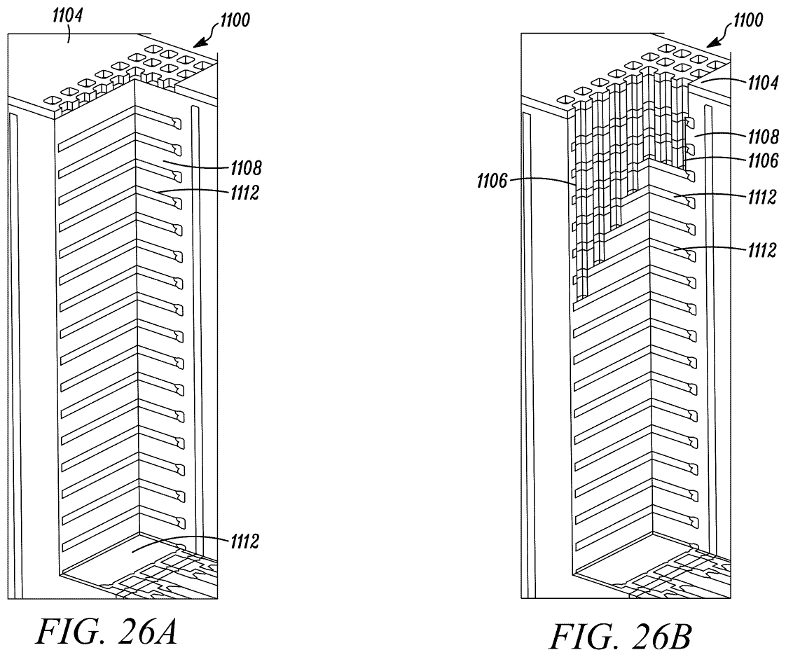

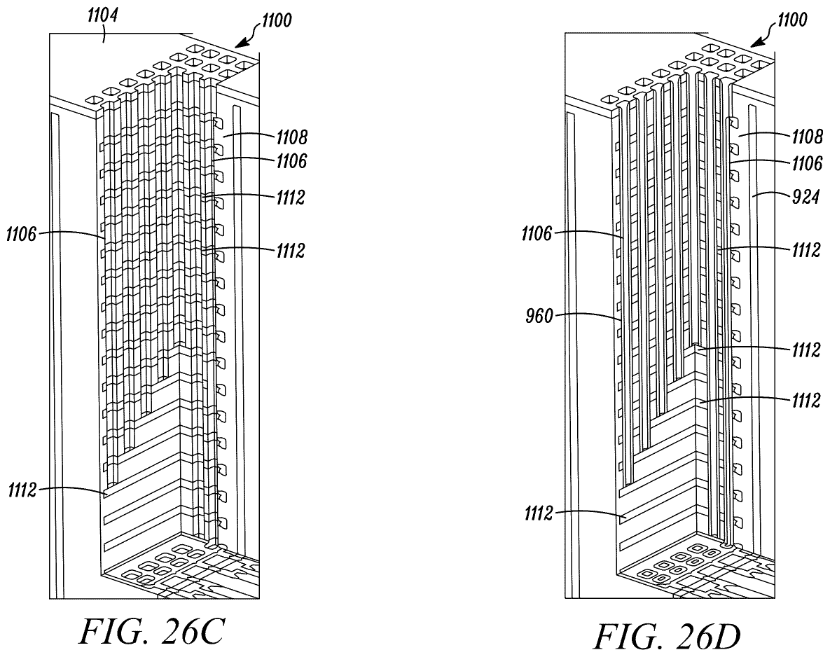

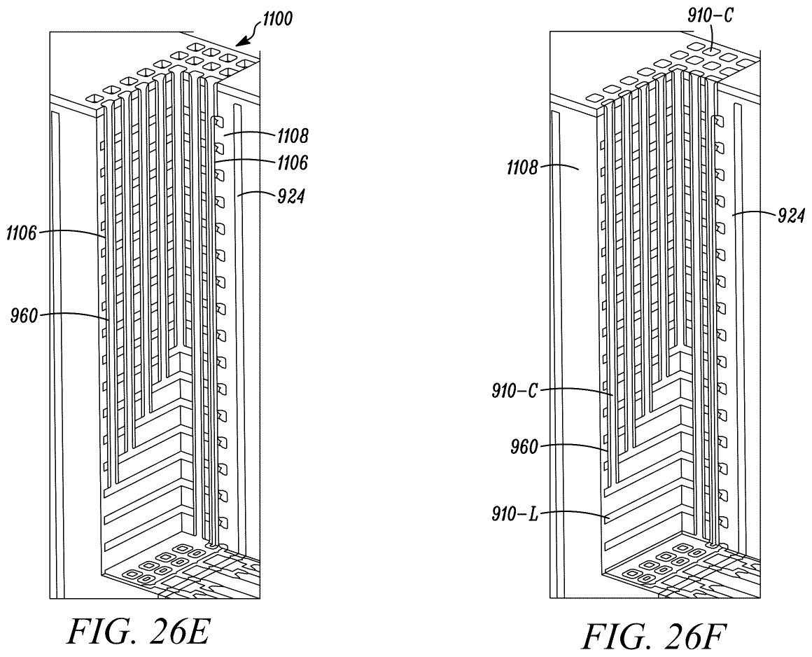

Referring now to FIGS. 26A to 26F, patterning of the bitline contacts 910-C forming the bitline contact bank is performed. In FIG. 26A, a hole array 1100 is patterned (e.g., a 4×7 hole array) in a nitride layer 1104. In FIGS. 26B and 26C, etching of vias 1106 is performed through oxide 1108 and silicon 1112 (in the silican (future location of the bitline layers 910-L)) to different etch depths (in other words, different landing elevations on the future bitlines layers 910-L) (defining the vertical bitlines 910-C). In FIG. 26D, isolation spacers (the insulated portions 960) for the vias 1106 are deposited in the vias 1106. In FIG. 26E, removal of silicon (corresponding to the bitline layers 910-L) is performed using wet etching and stopping on the multi-bridges 943 and 945. In FIG. 26F, the vias 1106 and other cavities are filled with conductor material (e.g., forming vertical bitlines 910-C and bitline layers 910-L).

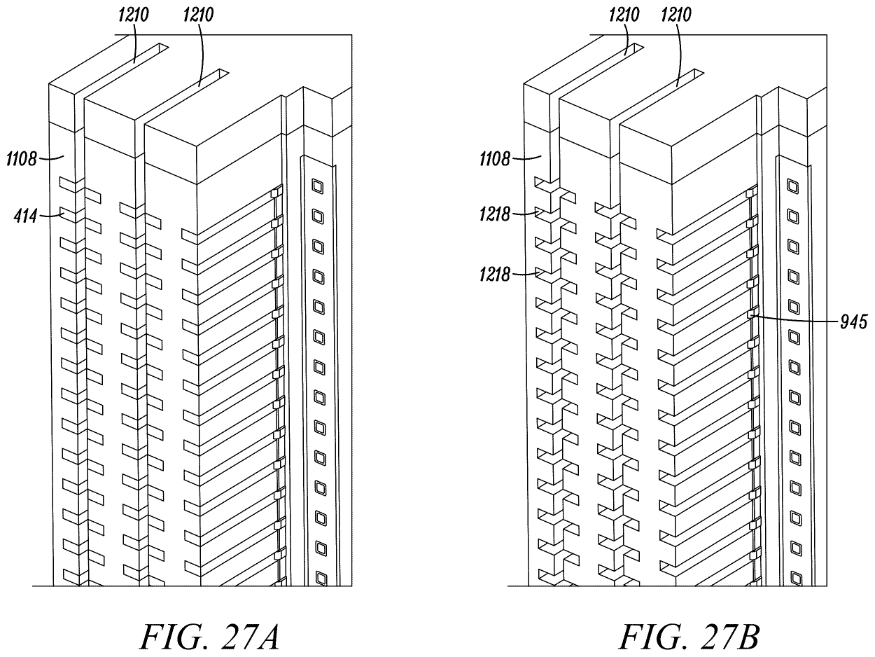

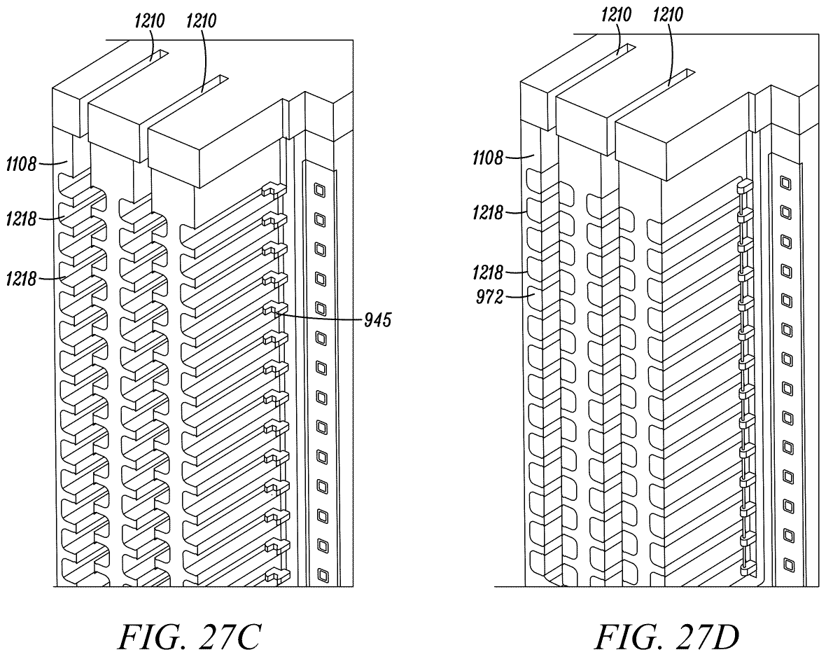

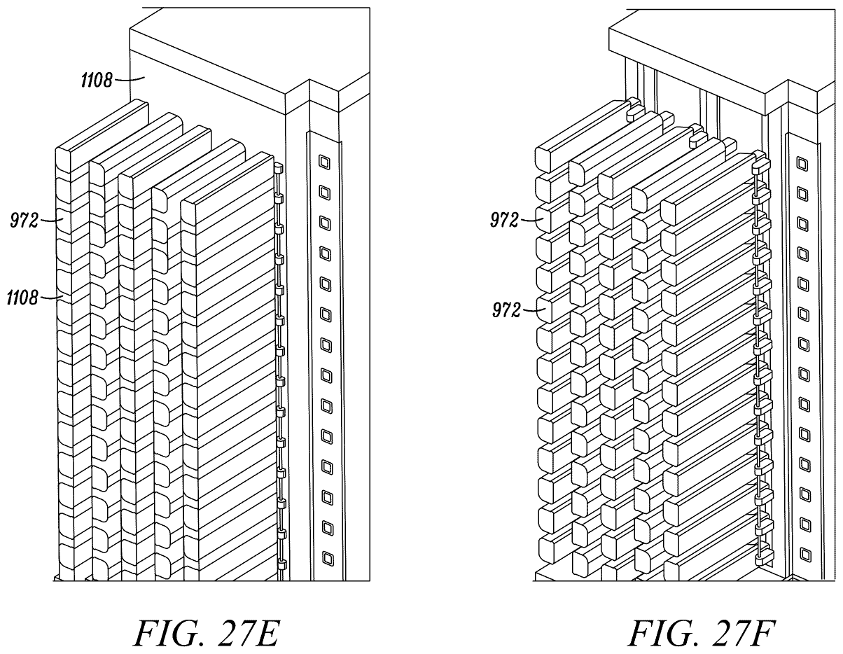

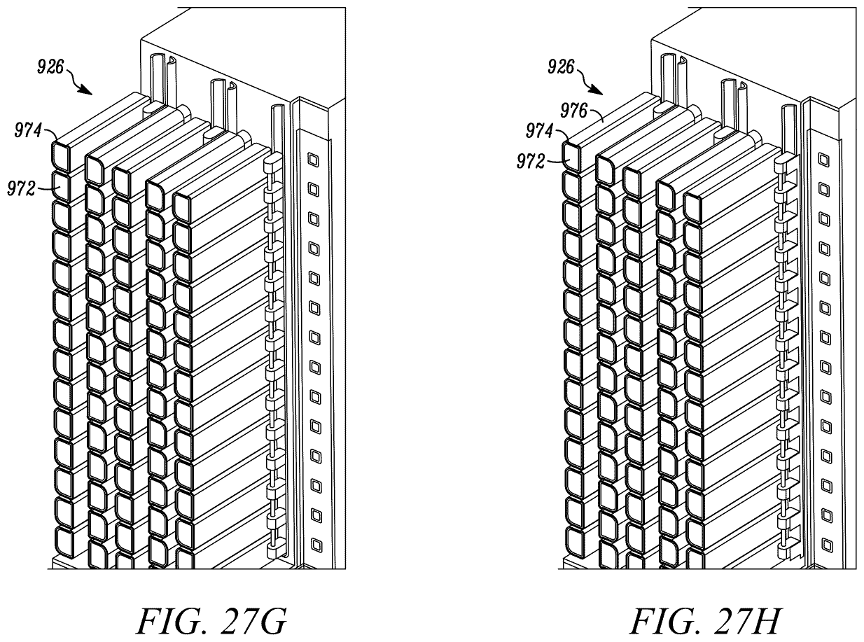

Referring now to FIGS. 27A to 27H, the capacitors are processed. In FIG. 27A, trenches 1210 are opened and etching of the oxide 1108 is performed. In FIG. 27B, etching of the silicon layers 414 is performed to form recesses 1218. In FIG. 27C, cavity widening is performed using an oxide isotropic etch to increase a diameter of the recesses 1218 for the inner metal layer 972 of the capacitors 926.

In FIG. 27D, a metal 1222 is deposited in the recesses 1218 to form the inner metal layer 972 of the capacitors 926. For example, one or more conformal deposition and anisotropic etch cycles are performed. In FIG. 27E, oxide deposition and oxide selective etch relative to TiN are performed. In FIG. 27F, oxide removal is performed. At 27G, the isolator layer 974 with a high dielectric constant k is deposited on the inner metal layer 972 of the capacitors 926. In FIG. 27H, an outer layer 976 of the capacitors 926 is deposited over the isolator layer 974.

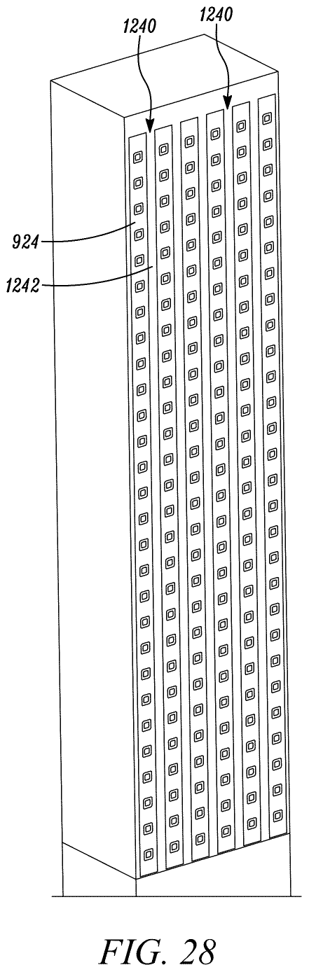

Referring now to FIG. 28, the gates or wordlines are separated or cut. A trench 1240 is etched in the gate metal in between the nanosheet transistors and filled with dielectric 1242.

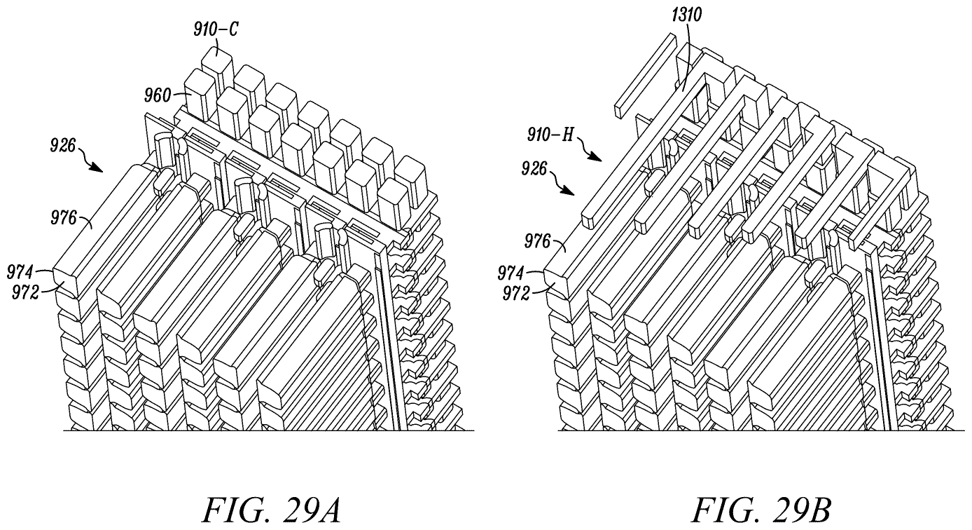

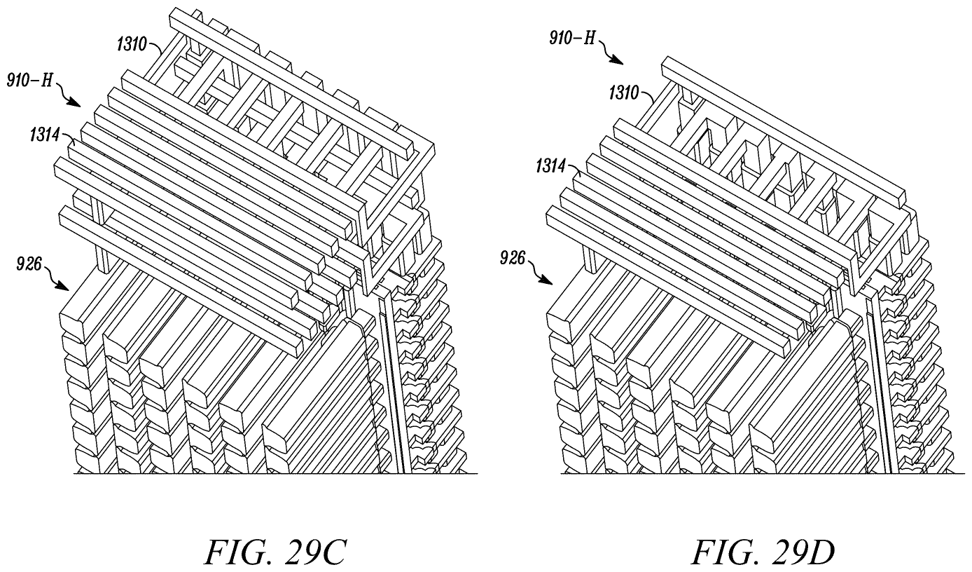

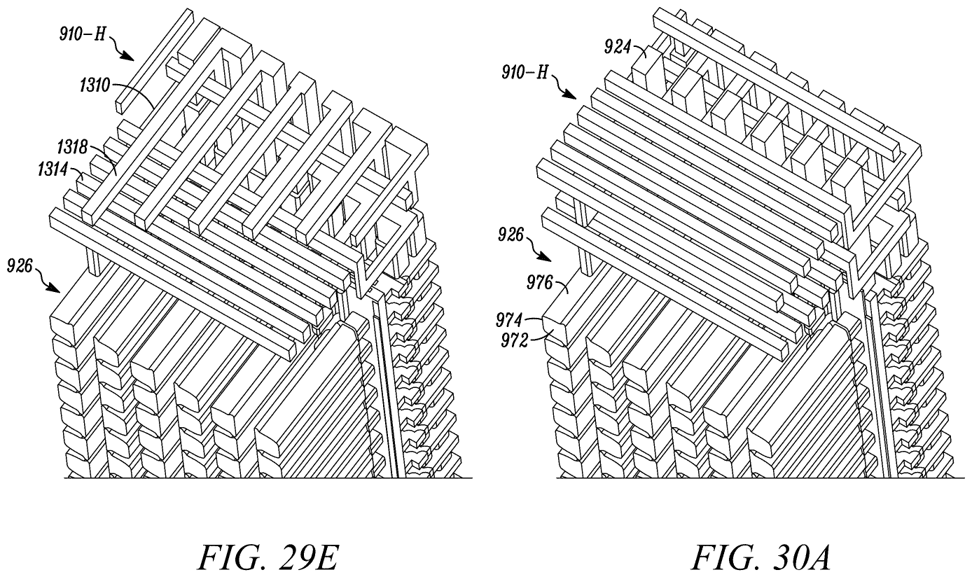

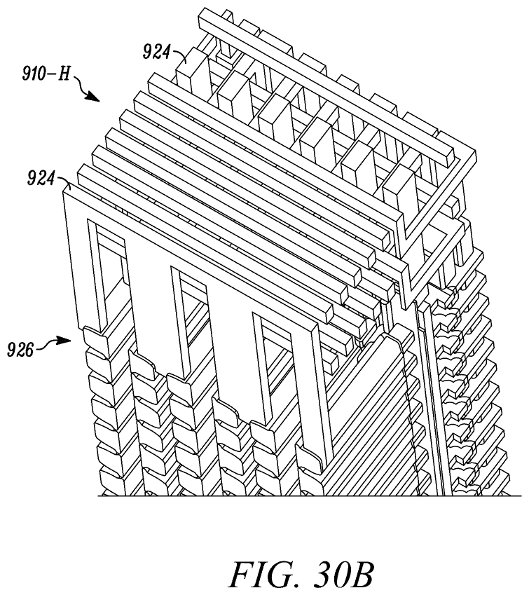

Referring now to FIGS. 29A to 30B, formation of the horizontal bitline contacts 910-H for the bitlines 910-C is performed. In FIGS. 29A and 29B, horizontal bitline contacts 1310 (e.g., 6 horizontal bitline contacts) are formed to re-route the bitlines over the capacitors 926. In FIG. 29C, horizontal bitline contacts 1314 (transverse to the horizontal bitline contacts 1310 and in a parallel plane) are patterned (e.g., 7 horizontal bitlines) is performed. In FIG. 29D, additional horizontal bitline contacts 1318 (e.g., 6 horizontal bitline contacts) are formed (over the horizontal bitline contacts) to re-route over the capacitors 926. In FIG. 29E, horizontal bitline patterning (e.g., 7 horizontal bitlines) is performed. In FIGS. 30A and 30B, formation of wordlines 924 and the capacitor ground (the contacts 940) to the outer layer 976 of the capacitors 926 is performed.

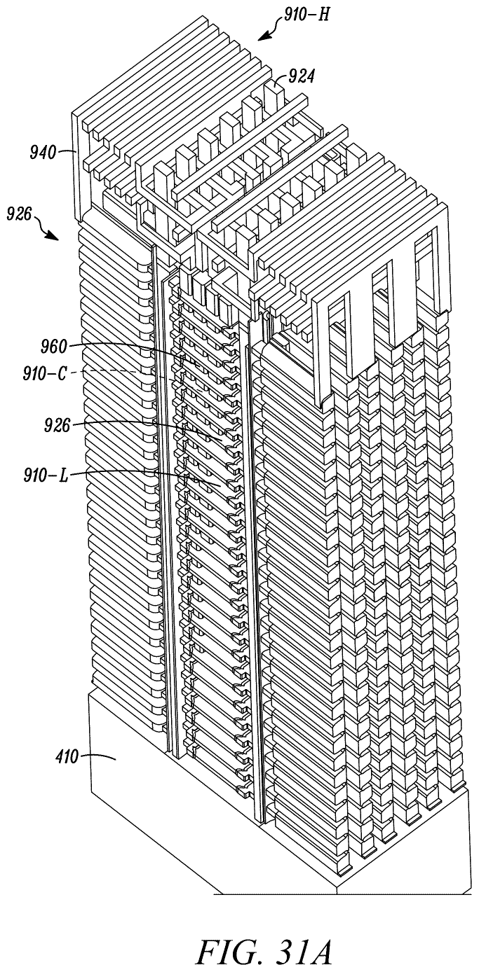

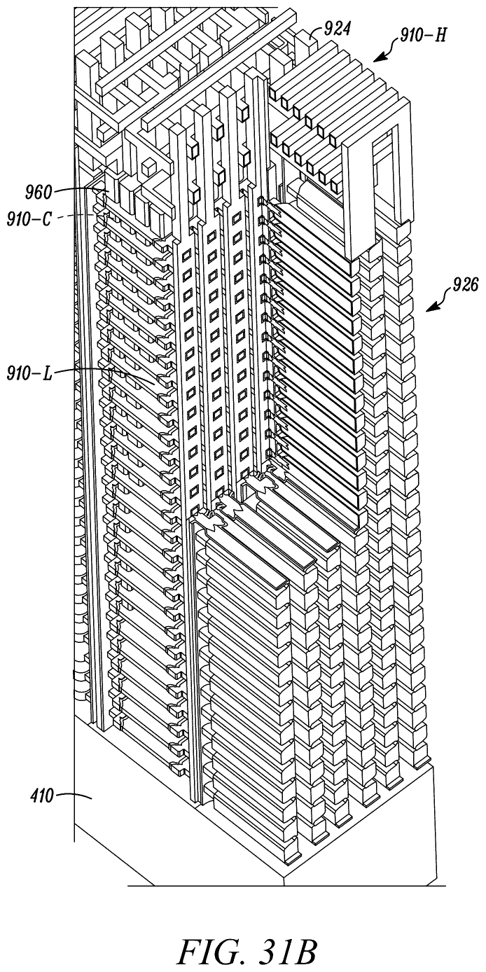

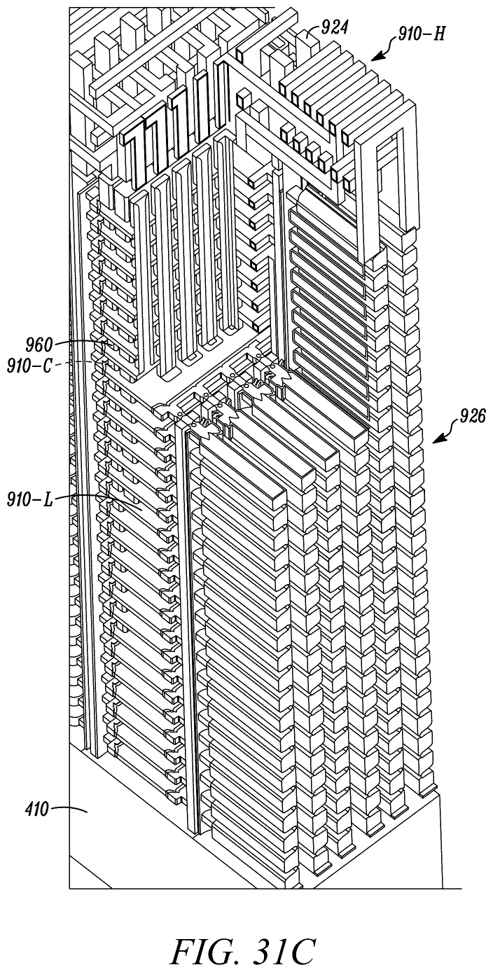

Referring now to FIGS. 31A to 31C, the 3D DRAM is shown with some layers removed to allow underlying structures to be viewed.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

What is claimed is:

1. A three-dimensional (3D) dynamic random-access memory (DRAM), comprising:
a substrate;
a plurality of nanosheet transistors stacked vertically on a surface of the substrate, wherein each of the nanosheet transistors comprises a gate, a source, and a drain;
a first staircase;
a plurality of bitline contacts;
a plurality of bitlines connected by the plurality of bitline contacts to corresponding ones of the drains of the nanosheet transistors at the first staircase;
a plurality of second staircases;
a plurality of third staircases;
a plurality of capacitor contacts;
a plurality of storage node contacts including first ends connected to corresponding ones of the sources of the plurality of nanosheet transistors; and
a plurality of capacitors stacked vertically on the substrate and extending parallel to a surface of the substrate,
wherein first ends of the plurality of capacitors located adjacent to the plurality of nanosheet transistors are connected to first ends of corresponding ones the plurality of capacitor contacts at corresponding ones of the plurality of second staircases,
wherein second ends of the plurality of capacitor contacts are connected to second ends of corresponding ones of the plurality of storage node contacts at corresponding ones of the plurality of third staircases.

2. The 3D-DRAM of claim 1, wherein the first staircase comprises a two-dimensional (2D) staircase.

3. The 3D-DRAM of claim 1, wherein the first staircase descends in first and second orthogonal directions relative to the surface of the substrate.

4. The 3D-DRAM of claim 1, wherein at least a portion of the first staircase extends below the surface of the substrate.

5. The 3D-DRAM of claim 1, wherein the first staircase and the plurality of bitlines are arranged on one side of the plurality of nanosheet transistors.

6. The 3D-DRAM of claim 4, wherein the plurality of second staircases, the plurality of third staircases, and the capacitors are arranged on an opposite side of the plurality of nanosheet transistors.

7. The 3D-DRAM of claim 1, wherein the capacitor contacts are J-shaped and have a plurality of vertical lengths in a direction transverse to the surface of the substrate.

8. The 3D-DRAM of claim 1, wherein the plurality of second staircases is interleaved between the plurality of third staircases.

9. The 3D-DRAM of claim 8, wherein:
the plurality of second staircases descends in a direction towards the plurality of nanosheet transistors; and
the plurality of third staircases ascends in a direction towards the plurality of nanosheet transistors.

10. The 3D-DRAM of claim 1, wherein the gates of the plurality of nanosheet transistors comprise forksheet gates corresponding to word lines.

11. A three-dimensional (3D) dynamic random-access memory (DRAM), comprising:
a substrate;
a plurality of nanosheet transistors stacked vertically on a surface of the substrate,
wherein each of the nanosheet transistors comprises a gate, a source, and a drain;
a plurality of bitlines connected to corresponding ones of the drains of the nanosheet transistors on one side of the plurality of nanosheet transistors; and
a plurality of capacitors stacked vertically on the substrate, extending parallel to a surface of the substrate, and connected to corresponding ones of the sources on an opposite side of the plurality of nanosheet transistors.

12. The 3D-DRAM of claim 11, further comprising:
a first staircase; and
a plurality of bitline contacts;
wherein the plurality of bitlines is connected by the plurality of bitline contacts to corresponding ones of the drains of the nanosheet transistors at the first staircase.

13. The 3D-DRAM of claim 12, further comprising:
a plurality of second staircases;
a plurality of third staircases;
a plurality of capacitor contacts; and
a plurality of storage node contacts including first ends connected to corresponding ones of the sources of the plurality of nanosheet transistors,
wherein first ends of the plurality of capacitors located adjacent to the plurality of nanosheet transistors are connected to first ends of corresponding ones the plurality of capacitor contacts at corresponding ones of the plurality of second staircases, and
wherein second ends of the plurality of capacitor contacts are connected to second ends of corresponding ones of the plurality of storage node contacts at corresponding ones of the plurality of third staircases.

14. The 3D-DRAM of claim 12, wherein the first staircase comprises a two-dimensional (2D) staircase.

15. The 3D-DRAM of claim 12, wherein the first staircase descends in first and second orthogonal directions relative to the surface of the substrate.

16. The 3D-DRAM of claim 12, wherein at least a portion of the first staircase extends below the surface of the substrate.

17. The 3D-DRAM of claim 13, wherein the capacitor contacts are J-shaped and have a plurality of vertical lengths in a direction transverse to the surface of the substrate.

18. The 3D-DRAM of claim 13, wherein the plurality of second staircases is interleaved between the plurality of third staircases.

19. The 3D-DRAM of claim 18, wherein:
the plurality of second staircases descends in a direction towards the plurality of nanosheet transistors; and
the plurality of third staircases ascends in a direction towards the plurality of nanosheet transistors.

20. The 3D-DRAM of claim 11, wherein the gates of the plurality of nanosheet transistors comprise forksheet gates corresponding to word lines.

21-50. (canceled)
